(19) United States
(12) Patent Application Publication
(10) Pub. No.: US 2024/0146210 A1
(43) Pub. Date: May 2, 2024

(54) POWER CONVERSION DEVICE

(71) Applicant: Mitsubishi Electric Corporation, Tokyo (JP)

(72) Inventor: Naoya YABUUCHI, Tokyo (JP)

(73) Assignee: Mitsubishi Electric Corporation, Tokyo (JP)

(21) Appl. No.: 18/475,728

(22) Filed: Sep. 27, 2023

(30) Foreign Application Priority Data
Oct. 26, 2022 (JP) 2022-171052

(51) Int. Cl. H02M 7/537; H02M 1/32; H02M 7/00; H02M 7/217

(52) U.S. Cl. CPC H02M 7/537; H02M 1/322; H02M 7/003; H02M 7/2173

(57) ABSTRACT

A power conversion device includes a power conversion circuit including semiconductor switching elements, a power supply wiring electrically connected to the power conversion circuit, a capacitor element, and a first capacitor connection wiring electrically connected between the power supply wiring and one electrode of the capacitor element and including a first opposed wiring portion having one end electrically connected to the power supply wiring and a second opposed wiring portion having another end electrically connected to one electrode of the capacitor element and disposed facing the first opposed wiring portion.

### TECHNICAL FIELD

The present disclosure relates to a power conversion device that converts a direct current into an alternating current, converts an alternating current into a direct current, or transforms a voltage.

### BACKGROUND ART

Patent Literature 1 discloses a method for preventing a capacitor constituting a filter circuit for reducing high-frequency noise caused by on/off of a switching element constituting an inverter from receiving heat due to heat generated in a connection conductor for power supply in a power conversion device including the inverter.

A power conversion device disclosed in Patent Literature 1 includes an inverter, a connection conductor that supplies power to the inverter, a filter circuit that includes a capacitor circuit and is mounted on the connection conductor, a conductor portion to which a capacitor constituting the filter circuit is electrically connected, the conductor portion serving as a wiring portion of the capacitor circuit, and a cooler on which the capacitor is placed, and has a structure in which the connection conductor, the conductor portion, and the cooler are arranged so as to overlap each other, and the conductor portion electrically connected to the connection conductor is in thermal contact with an extension portion of the cooler.

### CITATION LIST

### Patent Literature

Patent Literature 1: JP 2018-121406 A

### SUMMARY OF INVENTION

### Technical Problem

In the power conversion device disclosed in Patent Literature 1, the conductor portion serving as the wiring portion of the capacitor circuit is provided with the conductor pattern on the surface of the insulating resin plate. Therefore, when the conductor portion is made long to obtain necessary cooling for the conductor portion, parasitic inductance generated in the conductor portion increases, and impedance characteristics of the capacitor at high frequencies deteriorate.

That is, when the parasitic inductance generated in the conductor portion increases, the impedance with respect to the high frequency in the conductor portion increases, and the function as a filter is impaired in which the high frequency noise current generated by turning on and off the switching element hardly flows to the capacitor.

The present disclosure has been made in view of the above points, and an object of the present disclosure is to provide a power conversion device that reduces parasitic inductance in a capacitor connection wiring while suppressing heat reception to a capacitor due to heat generated in the power supply wiring from a capacitor connection wiring connected between a power supply wiring connected to a power conversion circuit having a semiconductor switching element and the capacitor.

### Solution to Problem

A power conversion device according to the present disclosure includes: a power conversion circuit including semiconductor switching elements; a power supply wiring electrically connected to the power conversion circuit; a capacitor element; and a first capacitor connection wiring electrically connected between the power supply wiring and one electrode of the capacitor element and including a first opposed wiring portion having a first end electrically connected to the power supply wiring and a second opposed wiring portion having a second end electrically connected to the one electrode of the capacitor element and disposed opposite to the first opposed wiring portion.

### Advantageous Effects of Invention

According to the present disclosure, it is possible to suppress heat reception by a capacitor and reduce parasitic inductance in a capacitor connection wiring connected between a power supply wiring connected to a power conversion circuit and the capacitor.

### BRIEF DESCRIPTION OF DRAWINGS

FIG. 1 is a schematic configuration diagram illustrating a power conversion device according to a first embodiment.

FIG. 2 is a top view illustrating a structure of an electric path from a power supply wiring on a positive electrode side to a housing in the power conversion device according to the first embodiment.

FIG. 3 is a cross-sectional view taken along line A-A of FIG. 2.

FIG. 4 is an equivalent circuit diagram in an electric path from a power supply wiring on a positive electrode side to a housing in the power conversion device according to the first embodiment.

FIG. 5 is a diagram illustrating a parasitic inductance and a thermal resistance of a first capacitor connection wiring on a positive electrode side in the power conversion device according to the first embodiment.

FIG. 6 is a diagram illustrating impedance characteristics of the first capacitor connection wiring on the positive electrode side in the power conversion device according to the first embodiment.

FIG. 7 is a top view illustrating a structure of an electric path from a power supply wiring on a positive electrode side to a housing in a power conversion device according to a second embodiment.

FIG. 8 is a cross-sectional view taken along line A-A of FIG. 7.

FIG. 9 is a top view illustrating a structure of an electric path from a power supply wiring on a positive electrode side to a housing in a power conversion device according to a third embodiment.

FIG. 10 is a cross-sectional view taken along line A-A of FIG. 9.

FIG. 11 is a top view illustrating a structure of an electric path from a power supply wiring on a positive electrode side to a housing in a power conversion device according to a fourth embodiment.

FIG. 12 is a cross-sectional view taken along line A-A of FIG. 11.

FIG. 13 is a top view illustrating a structure of an electric path from a power supply wiring on a positive electrode side to a housing in a power conversion device according to a fifth embodiment.

FIG. 14 is a cross-sectional view taken along line A-A of FIG. 13.

FIG. 15 is a top view illustrating a structure of an electric path from a power supply wiring on a positive electrode side to a housing in a power conversion device according to a sixth embodiment.

FIG. 16 is a cross-sectional view taken along line A-A of FIG. 15.

FIG. 17 is an equivalent circuit diagram in an electric path from the power supply wiring on the positive electrode side to the housing in the power conversion device according to the sixth embodiment.

FIG. 18 is a top view illustrating a structure of an electric path from a power supply wiring on a positive electrode side to a housing in a power conversion device according to a seventh embodiment.

FIG. 19 is a cross-sectional view taken along line A-A of FIG. 18.

FIG. 20 is an equivalent circuit diagram in the electric path from the power supply wiring on the positive electrode side to the housing in the power conversion device according to the seventh embodiment.

FIG. 21 is a top view illustrating a structure of an electric path from a power supply wiring on a positive electrode side to a housing in a power conversion device according to an eighth embodiment.

FIG. 22 is a cross-sectional view taken along line A-A of FIG. 21.

FIG. 23 is a top view illustrating a structure of an electric path from a power supply wiring on a positive electrode side to a housing in a power conversion device according to a ninth embodiment.

FIG. 24 is a cross-sectional view taken along line A-A of FIG. 23.

FIG. 25 is a top view illustrating a structure of an electric path from a power supply wiring on a positive electrode side to a housing in a power conversion device according to a tenth embodiment.

FIG. 26 is a cross-sectional view taken along line A-A of FIG. 25.

FIG. 27 is a top view illustrating a structure of an electric path from a power supply wiring on a positive electrode side to a housing in a power conversion device according to an eleventh embodiment.

FIG. 28 is a cross-sectional view taken along line A-A of FIG. 27.

FIG. 29 is a cross-sectional view taken along line B-B of FIG. 27.

FIG. 30 is a cross-sectional view taken along line C-C in FIG. 27.

FIG. 31 is a diagram illustrating on-off drive characteristics in a case where a wide-gap semiconductor element is used as a switching element in a power conversion device according to a twelfth embodiment.

FIG. 32 is a diagram showing frequency characteristics of the wide-gap semiconductor element in the power conversion device according to the twelfth embodiment.

### DESCRIPTION OF EMBODIMENTS

### First Embodiment

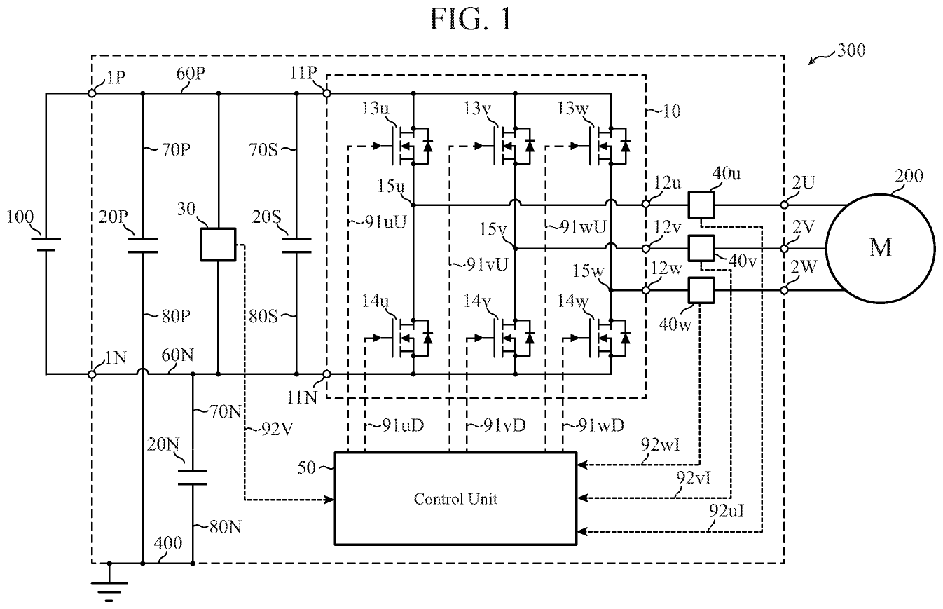

A power conversion device according to a first embodiment will be described with reference to FIGS. 1 to 6.

A power conversion device 300 according to the first embodiment includes a power conversion circuit 10 that is a three-phase inverter circuit that converts DC power from a power supply 100 into three-phase AC power, and supplies the three-phase AC power to a load 200.

However, the power conversion device 300 according to the first embodiment is not limited to a power conversion device including a three-phase inverter circuit that converts direct current into three-phase alternating current, and may be a power conversion device including a single-phase inverter circuit that converts direct current into single-phase alternating current, a power conversion device including a converter circuit that converts alternating current into direct current, or a power conversion device including a DC-DC converter circuit that transforms voltage.

Note that the power conversion circuit is a term including any of a three-phase inverter circuit, a single-phase inverter circuit, a converter circuit, and a DC-DC converter circuit.

Hereinafter, a power conversion device 300 including a power conversion circuit 10 that is a three-phase inverter circuit that converts a direct current into a three-phase alternating current will be described.

In a case where the power conversion device 300 is used in an electric vehicle or a hybrid vehicle, the power supply 100 is, for example, a secondary battery such as a nickel-metal hydride battery or a lithium ion battery.

In the power supply 100, a positive electrode is electrically connected to a positive electrode-side input terminal 1P of the power conversion device 300, and a negative electrode is electrically connected to a negative electrode-side input terminal 1N of the power conversion device 300, and the power supply 100 supplies DC power to the power conversion device 300.

The load 200 is a three-phase motor that is an electric motor.

In the load 200, a U-phase input terminal is electrically connected to a u-phase output terminal 2U of the power conversion device 300, a V-phase input terminal is electrically connected to a v-phase output terminal 2V of the power conversion device 300, a W-phase input terminal is electrically connected to a w-phase output terminal 2W of the power conversion device 300, and three-phase AC power is supplied from the power conversion device 300 to the load 200.

Note that, in the case of a power conversion device including a converter circuit that converts three-phase AC into DC, the power supply 100 is a three-phase motor that is a generator, and the load 200 is a secondary battery.

The power conversion device 300 according to the first embodiment is housed in a metal housing 400.

The metal housing 400 is grounded. The metal housing 400 is integrated with a cooler (not shown).

Note that, in the drawing, for convenience of explanation, the power conversion device 300 is illustrated as being housed in the metal housing 400 but disposed outside the metal housing 400. The metal housing 400 itself also functions as a ground node for the power conversion device 300.

As illustrated in FIG. 1, the power conversion device 300 according to the first embodiment includes a power conversion circuit 10, a positive electrode-side noise-removing capacitor element 20P, a negative electrode-side noise-removing capacitor element 20N, a smoothing capacitor element 20S, a direct-current voltage sensor circuit 30, a u-phase current sensor circuit 40u, a v-phase current sensor circuit 40v, a w-phase current sensor circuit 40w, a control unit 50, a positive electrode-side power supply wiring 60P, a negative electrode-side power supply wiring 60N, a first capacitor connection wiring 70P for positive electrode-side capacitor element 20P connection, a second capacitor connection wiring 80P for positive electrode-side capacitor element 20P connection, a first capacitor connection wiring 70N for negative electrode-side capacitor element 20N connection, a second capacitor connection wiring 80N for negative electrode-side capacitor element 20N connection, a first capacitor connection wiring 70S for smoothing capacitor element 20S connection, a second capacitor connection wiring 80S for smoothing capacitor element 20S connection, control lines 91uU, 91uD, 91vU, 91vD, 91wU, 91wD, and signal lines 92V, 92uI, 92vI, 92wI.

The power conversion circuit 10 is a switching circuit including semiconductor switching elements for controlling power.

The power conversion circuit 10 is a three-phase inverter circuit constituted by a three-phase bridge rectifier circuit (three-phase full-wave rectifier circuit) constituted by semiconductor switching element groups 13u, 14u, 13v, 14v, 13w, and 14w.

The semiconductor switching element group 13u is a u-phase upper arm semiconductor switching element group, and is electrically connected between a positive electrode-side input node 11P and a u-phase output node 15u.

The positive electrode-side input node 11P is electrically connected to a positive electrode-side input terminal 1P of the power conversion device 300 via a positive electrode-side power supply wiring 60P.

The u-phase output node 15u is electrically connected to a u-phase output terminal 12u of the power conversion circuit 10 via a u-phase power supply wiring.

The u-phase output terminal 12u is electrically connected to a u-phase output terminal 2U of the power conversion device 300 via a u-phase power supply wiring.

The semiconductor switching element group 13u includes one or a plurality of semiconductor switching elements connected in parallel, and diode elements connected in anti-parallel with the semiconductor switching elements and operating as free-wheeling diodes.

The semiconductor switching element is an N-type metal oxide semiconductor field effect transistor (MOSFET).

Note that the semiconductor switching element may be an insulated gate bipolar transistor (IGBT) instead of the MOSFET.

In the semiconductor switching element, a drain electrode is electrically connected to the input node 11P, a source electrode is electrically connected to the u-phase output node 15u, and a gate electrode is electrically connected to the control unit 50 via the control line 91uU.

In the semiconductor switching element, a control signal from the control unit 50 is input to the gate electrode via the control line 91uU, ON/OFF control is performed with a dead time interposed therebetween, and a semiconductor switching operation is performed.

In the diode element, a cathode electrode is electrically connected to a drain electrode of the semiconductor switching element, and an anode electrode is electrically connected to a source electrode of the semiconductor switching element.

The semiconductor switching element group 14u is a u-phase lower arm semiconductor switching element group, and is electrically connected between the u-phase output node 15u and the negative electrode-side input node 11N.

The negative electrode-side input node 11N is electrically connected to the negative electrode-side input terminal 1N of the power conversion device 300 via the negative electrode-side power supply wiring 60N.

The semiconductor switching element group 14u includes one or a plurality of semiconductor switching elements connected in parallel, and diode elements connected in anti-parallel with the semiconductor switching elements and operating as free-wheeling diodes.

The semiconductor switching element may be a MOSFET or an IGBT.

In the semiconductor switching element, the drain electrode is electrically connected to the u-phase output node 15u, the source electrode is electrically connected to the input node 11N, and the gate electrode is electrically connected to the control unit 50 via the control line 91uD.

In the semiconductor switching element, a control signal from the control unit 50 is input to the gate electrode via the control line 91uD, ON/OFF control is performed with a dead time interposed therebetween, and a semiconductor switching operation is performed.

In the diode element, a cathode electrode is electrically connected to a drain electrode of the semiconductor switching element, and an anode electrode is electrically connected to a source electrode of the semiconductor switching element.

The semiconductor switching element group 13v is a v-phase upper arm semiconductor switching element group, and is electrically connected between the positive electrode-side input node 11P and a v-phase output node 15v.

The v-phase output node 15v is electrically connected to the v-phase output terminal 12v of the power conversion circuit 10 via a v-phase power supply wiring.

The v-phase output terminal 12v is electrically connected to a v-phase output terminal 2V of the power conversion device 300 via a v-phase power supply wiring.

The semiconductor switching element group 13v includes one or a plurality of semiconductor switching elements connected in parallel, and diode elements connected in anti-parallel with the semiconductor switching elements and operating as free-wheeling diodes.

The semiconductor switching element may be a MOSFET or an IGBT.

In the semiconductor switching element, a drain electrode is electrically connected to the input node 11P, a source electrode is electrically connected to the v-phase output node 15v, and a gate electrode is electrically connected to the control unit 50 via the control line 91vU.

In the semiconductor switching element, a control signal from the control unit 50 is input to the gate electrode via the control line 91vU, ON/OFF control is performed with a dead time interposed therebetween, and a semiconductor switching operation is performed.

In the diode element, a cathode electrode is electrically connected to a drain electrode of the semiconductor switching element, and an anode electrode is electrically connected to a source electrode of the semiconductor switching element.

The semiconductor switching element group 14v is a v-phase lower arm semiconductor switching element group, and is electrically connected between the v-phase output node 15v and the negative electrode-side input node 11N.

The semiconductor switching element group 14v includes one or a plurality of semiconductor switching elements connected in parallel, and diode elements connected in anti-parallel with the semiconductor switching elements and operating as free-wheeling diodes.

The semiconductor switching element may be a MOSFET or an IGBT.

In the semiconductor switching element, the drain electrode is electrically connected to the v-phase output node 15v, the source electrode is electrically connected to the input node 11N, and the gate electrode is electrically connected to the control unit 50 via the control line 91vD.

In the semiconductor switching element, a control signal from the control unit 50 is input to the gate electrode via the control line 91vD, ON/OFF control is performed with a dead time interposed therebetween, and a semiconductor switching operation is performed.

In the diode element, a cathode electrode is electrically connected to a drain electrode of the semiconductor switching element, and an anode electrode is electrically connected to a source electrode of the semiconductor switching element.

The semiconductor switching element group 13w is a w-phase upper arm semiconductor switching element group, and is electrically connected between the positive electrode-side input node 11P and the w-phase output node 15w.

The w-phase output node 15w is electrically connected to the w-phase output terminal 12w of the power conversion circuit 10 via a w-phase power supply wiring.

The w-phase output terminal 12w is electrically connected to the w-phase output terminal 2W of the power conversion device 300 via the w-phase power supply wiring.

The semiconductor switching element group 13w includes one or a plurality of semiconductor switching elements connected in parallel, and diode elements connected in anti-parallel with the semiconductor switching elements and operating as free-wheeling diodes.

The semiconductor switching element may be a MOSFET or an IGBT.

In the semiconductor switching element, the drain electrode is electrically connected to the input node 11P, the source electrode is electrically connected to the w-phase output node 15w, and the gate electrode is electrically connected to the control unit 50 via the control line 91wU.

In the semiconductor switching element, a control signal from the control unit 50 is input to the gate electrode via the control line 91wU, ON/OFF control is performed with a dead time interposed therebetween, and a semiconductor switching operation is performed.

In the diode element, a cathode electrode is electrically connected to a drain electrode of the semiconductor switching element, and an anode electrode is electrically connected to a source electrode of the semiconductor switching element.

The semiconductor switching element group 14w is a w-phase lower arm semiconductor switching element group, and is electrically connected between the w-phase output node 15w and the negative electrode-side input node 11N.

The semiconductor switching element group 14w includes one or a plurality of semiconductor switching elements connected in parallel, and diode elements connected in anti-parallel with the semiconductor switching elements and operating as free wheeling diodes.

The semiconductor switching element may be a MOSFET or an IGBT.

In the semiconductor switching element, a drain electrode is electrically connected to the w-phase output node 15w, a source electrode is electrically connected to the input node 11N, and a gate electrode is electrically connected to the control unit 50 via the control line 91wD.

In the semiconductor switching element, a control signal from the control unit 50 is input to the gate electrode via the control line 91wD, ON/OFF control is performed with a dead time interposed therebetween, and a semiconductor switching operation is performed.

In the diode element, a cathode electrode is electrically connected to a drain electrode of the semiconductor switching element, and an anode electrode is electrically connected to a source electrode of the semiconductor switching element.

Each of the semiconductor switching element groups 13u, 14u, 13v, 14v, 13w, and 14w may be configured using an individual power module, or may be configured as one power module incorporating all of the semiconductor switching element groups 13u, 14u, 13v, 14v, 13w, and 14w.

The capacitor element 20P is a Y capacitor that suppresses a common mode noise current superimposed on the positive electrode-side power supply wiring 60P.

The capacitor element 20P is a positive electrode-side noise removal capacitor that is connected between the power supply wiring 60P and a ground node serving as a reference ground, i.e., metal housing 400 in the present example, and plays a role of preventing a common mode noise current from flowing toward the power supply wiring 60P. In the capacitor element 20P, one electrode is electrically connected to the power supply wiring 60P via the first capacitor connection wiring 70P, and the other electrode is electrically connected to the ground node via the second capacitor connection wiring 80P.

The capacitor element 20P is not limited to one capacitor element, and includes a plurality of capacitor elements connected in parallel or a plurality of capacitor elements connected in series.

The capacitor element 20N is a Y capacitor that suppresses a common mode noise current superimposed on the negative electrode-side power supply wiring 60N.

The capacitor element 20N is a negative electrode-side noise removal capacitor that is connected between the power supply wiring 60N and the ground node and plays a role of preventing a common mode noise current from flowing toward the power supply wiring 60N.

In capacitor element 20N, one electrode is electrically connected to the power supply wiring 60N via the first capacitor connection wiring 70N, and the other electrode is electrically connected to the ground node via the second capacitor connection wiring 80N.

The capacitor element 20N is not limited to one capacitor element, and includes a plurality of capacitor elements connected in parallel or a plurality of capacitor elements connected in series.

The capacitor element 20S is a smoothing capacitor element that removes voltage ripples and noise appearing in the positive electrode-side power supply wiring 60P and the negative electrode-side power supply wiring 60N.

In the capacitor element 20S, one electrode is electrically connected to the power supply wiring 60P via the first capacitor connection wiring 70S, and the other electrode is electrically connected to the power supply wiring 60N via the second capacitor connection wiring 80S.

The voltage sensor circuit 30 is connected between the power supply wiring 60P and the power supply wiring 60N, that is, in parallel to the capacitor element 20S, and detects a DC voltage between the power supply wiring 60P and the power supply wiring 60N, that is, an input voltage of the power conversion device 300.

The result detected by the voltage sensor circuit 30, that is, the input DC voltage value of the power conversion device 300 is output from the voltage sensor circuit 30 to the control unit 50 via the signal line 92V.

The u-phase current sensor circuit 40u detects the u-phase output current flowing through the u-phase power supply wiring connected to the u-phase output terminal 12u.

The u-phase output current detected by the current sensor circuit 40u is output from the current sensor circuit 40u to the control unit 50 via the signal line 92uI.

The v-phase current sensor circuit 40v detects a v-phase output current flowing through the v-phase power supply wiring connected to the v-phase output terminal 12v.

The v-phase output current detected by the current sensor circuit 40v is output from the current sensor circuit 40v to the control unit 50 via the signal line 92vI.

The w-phase current sensor circuit 40w detects the w-phase output current flowing through the w-phase power supply wiring connected to the w-phase output terminal 12v.

The w-phase output current detected by the current sensor circuit 40w is output from the current sensor circuit 40w to the control unit 50 via the signal line 92wI.

The control unit 50 acquires information of the input voltage in the power conversion device 300 from the voltage sensor circuit 30 via the signal line 92V, and acquires information of the output currents in the u phase, the v phase, and the w phase of the power conversion device 300 from the current sensor circuit 40u, the current sensor circuit 40v, and the current sensor circuit 40w via the signal line 92uI, the signal line 92vI, and the signal line 92wI, respectively.

The control unit 50 applies control signals to the gate electrodes of the semiconductor switching elements in the semiconductor switching element group 13u, the semiconductor switching element group 14u, the semiconductor switching element group 13v, the semiconductor switching element group 14v, the semiconductor switching element group 13w, and the semiconductor switching element group 14w via the control line 91uU, the control line 91uD, the control line 91vU, the control line 91vD, the control line 91wU, and the control line 91wD, respectively, and performs on/off control of each semiconductor switching element with a dead time interposed therebetween.

When on/off control of each semiconductor switching element is performed by the control unit 50, the DC current from the power supply 100 smoothed by the smoothing capacitor element 20S is converted into a three-phase current by the power conversion circuit 10 and supplied to the load 200.

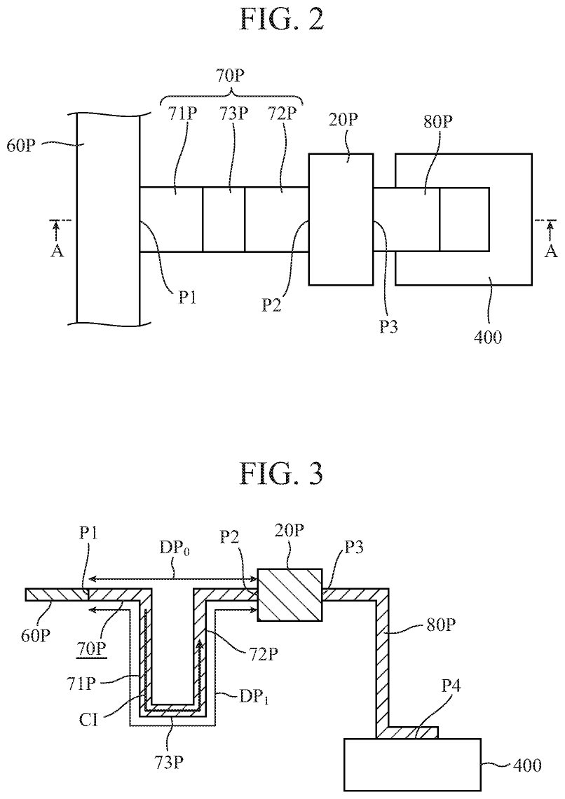

Next, a structure of an electric path from the positive electrode-side power supply wiring 60P to the metal housing 400 serving as a ground node via the positive electrode-side noise-removing capacitor element 20P will be described with reference to FIGS. 2 and 3.

The positive electrode-side power supply wiring 60P is a power supply wiring electrically connected to the power conversion circuit 10.

The power supply wiring 60P is a flat plate-like conductor having front and back surfaces.

In the power supply wiring 60P, one end is connected to the positive electrode-side input terminal 1P to which the positive electrode of the DC power supply 100 is connected, and the other end is connected to the positive electrode-side input node 11P of the power conversion circuit 10.

The first capacitor connection wiring 70P is electrically connected between the power supply wiring 60P and one electrode of the capacitor element 20P.

The first capacitor connection wiring 70P is a flat plate-like conductor having front and back surfaces.

In the first capacitor connection wiring 70P, one end surface is connected to the side surface of the power supply wiring 60P at a first connection point P1, and the other end is connected to one electrode terminal connected to one electrode of the capacitor element 20P at a second connection point P2.

The first capacitor connection wiring 70P includes a first opposed wiring portion 71P having one end electrically connected to the power supply wiring 60P at the first connection point P1, a second opposed wiring portion 72P having the other end electrically connected to one electrode terminal of the capacitor element 20P at the second connection point P2 and having an opposed portion disposed opposite to an opposed portion of the first opposed wiring portion 71P, and a bent wiring portion 73P electrically connecting the other end of the first opposed wiring portion 71P and one end of the second opposed wiring portion 72b.

The first opposed wiring portion 71P, the second opposed wiring portion 72P, and the bent wiring portion 73P are a flat plate-like conductor formed integrally.

The one end surface of the first opposed wiring portion 71P is electrically and mechanically connected to the side surface of the power supply wiring 60P at the first connection point P1 by soldering, welding, screwing, or the like.

The first opposed wiring portion 71P has an extending portion extending from one end surface connected to the side surface of the power supply wiring 60P at the first connection point P1 in the direction of one electrode terminal of the capacitor element 20P and an opposed portion bent at a right angle from the extending portion in a direction away from the side surface of the power supply wiring 60P with respect to the front and back surfaces on the same plane as the front and back surfaces of the power supply wiring 60P.

The other end of the second opposed wiring portion 72P is electrically and mechanically connected to one electrode terminal of the capacitor element 20P at the second connection point P2 by soldering or the like.

The second opposed wiring portion 72P has an extending portion extending from the other end connected to one electrode terminal of the capacitor element 20P in the direction of the power supply wiring 60P at the second connection point P2, and an opposed portion that is bent at a right angle from the extending portion in the direction away from the capacitor element 20P with respect to the front and back surfaces, and has a surface that faces the surface of the opposed portion in the first opposed wiring portion 71P at equal intervals on the same plane as the front and back surfaces of the first opposed wiring portion 71P.

The bent wiring portion 73P is continuously formed between the other end of the opposed portion in the first opposed wiring portion 71P and one end of the opposed portion in the second opposed wiring portion 72P.

The front and back surfaces of the bent wiring portion 73P are parallel to the front and back surfaces of the extending portion in the first opposed wiring portion 71P and the front and back surfaces of the extending portion in the second opposed wiring portion 72P.

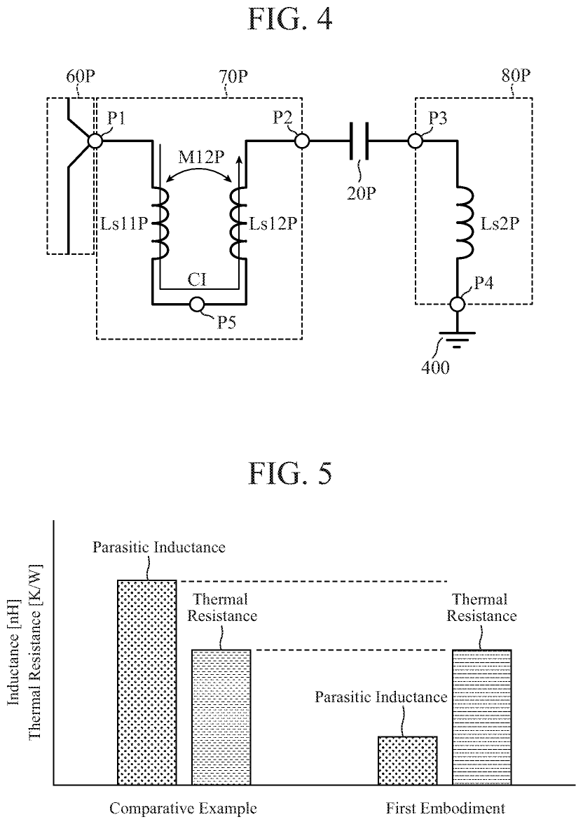

Although the bent wiring portion 73P has a flat surface, the first capacitor connection wiring 70P may have a U-shape in FIG. 4 as an entire shape thereof with the bent wiring portion 73P as a curved surface, or the first capacitor connection wiring 70P may have a V-shape in FIG. 4 as an entire shape thereof with the bent wiring portion 73P as a straight line.

That is, the first capacitor connection wiring 70P only needs to have a structure in which a part thereof is arranged to face each other, that is, a structure in which the first opposed wiring portion 71P and the second opposed wiring portion 72P are continuously, that is, integrally formed, and the opposed portion in the first opposed wiring portion 71P and the opposed portion in the second opposed wiring portion 72P are arranged to face each other.

The second capacitor connection wiring 80P is electrically connected between the other electrode terminal to which the other electrode of the capacitor element 20P is connected and the metal housing 400.

The second capacitor connection wiring 80P is a flat plate-like conductor having front and back surfaces.

In the second capacitor connection wiring 80P, one end is electrically and mechanically connected to the other electrode terminal of the capacitor element 20P at a third connection point P3 by soldering or the like, and the other end is electrically and mechanically connected to the metal housing 400 at a fourth connection point P4 by soldering, welding, screwing, or the like.

A common mode noise current CI flows to the capacitor element 20P through the first capacitor connection wiring 70P.

Opposed electrode terminals in the capacitor element 20P are arranged in a direction orthogonal to the extending portion in the first opposed wiring portion 71P and the extending portion in the second opposed wiring portion 72P.

That is, the flowing direction of the common mode noise current CI flowing through the capacitor element 20P and the flowing direction of the common mode noise current CI flowing through the extending portion in the first opposed wiring portion 71P and the extending portion in the second opposed wiring portion 72P are on the same plane.

Since the opposed portion in the first opposed wiring portion 71P and the opposed portion in the second opposed wiring portion 72P are provided, a wiring length DP₁ of the first capacitor connection wiring 70P becomes longer than a linear distance DP₀ from the first connection point P1, which is the connection point between one end surface of the first capacitor connection wiring 70P and the side surface of the power supply wiring 60P, to the second connection point P2, which is the connection point between the other end of the first capacitor connection wiring 70P and one electrode terminal of the capacitor element 20P.

Therefore, since the thermal resistance of the first capacitor connection wiring 70P can be increased, heat generated in the power supply wiring 60P is less likely to be transferred to the capacitor element 20P by the first capacitor connection wiring 70P.

In short, it is possible to suppress heat reception of the capacitor element 20P due to heat generated in the power supply wiring 60P.

That is, the thermal resistance Rth of the first capacitor connection wiring 70P is expressed by the following Formula (1).

Rth=(1/λ)×(D/A) (1)

In Formula (1), λ represents a thermal conductivity, D represents a length, and A represents a cross-sectional area.

As understood from Formula (1), the thermal resistance Rth of the first capacitor connection wiring 70P is proportional to the length D of the first capacitor connection wiring 70P, and the thermal resistance Rth increases as the length D increases.

Next, the parasitic inductance in the first capacitor connection wiring 70P will be described with reference to FIGS. 4 and 5.

FIG. 4 is an equivalent circuit diagram of an electric path from the power supply wiring 60P to the ground node (metal housing 400) via the capacitor element 20P.

A first self-inductance Ls11P is an inductance from one end (first connection point P1) in the first capacitor connection wiring 70P to an intermediate point P5 of the bent wiring portion 73P of the first opposed wiring portion 71P.

A second self-inductance Ls12P is an inductance from the intermediate point P5 of the bent wiring portion 73P to the other end (second connection point P2) of the second opposed wiring portion 72P in the first capacitor connection wiring 70P.

When the common mode noise current CI flows through the first capacitor connection wiring 70P, the current flowing through the first opposed wiring portion 71P and the current flowing through the second opposed wiring portion 72P are in opposite directions, so that the magnetic fluxes generated by the first opposed wiring portion 71P and the second opposed wiring portion 72P act to cancel each other out.

Therefore, a first parasitic inductance L11P from one end of the first opposed wiring portion 71P to the intermediate point P5 of the bent wiring portion 73P in the first capacitor connection wiring 70P is expressed by the following Formula (2).

In addition, a second parasitic inductance L12P from the midpoint of the bent wiring portion 73P to the other end P2 of the second opposed wiring portion 72P in the first capacitor connection wiring 70P is expressed by the following Formula (3).

As a result, a parasitic inductance L1P from one end (first connection point P1) to the other end (second connection point P2) in the first capacitor connection wiring 70P is expressed by the following Formula (4).

$$L 11 P = Ls 11 P - M 12 P \qquad ( 2 )$$

$$L 12 P = L s 12 P - M 12 P \qquad ( 3 )$$

$$\begin{matrix}L 1 P = L 11 P + L 12 P \\ = Ls 11 P + Ls 12 P - 2 \times M 12 P\end{matrix} \qquad ( 4 )$$

In Formulae (2) to (4), M12P is mutual inductance due to the first opposed wiring portion 71P and the second opposed wiring portion 72P.

As understood from Formula (4), when the lengths of the first capacitor connection wirings 70P are the same, the parasitic inductance L1P in the present example in which the first opposed wiring portion 71P and the second opposed wiring portion 72P are provided in the first capacitor connection wiring 70P is smaller by (2×M12P) than the parasitic inductance of the first capacitor connection wiring in the comparative example in which the first opposed wiring portion 71P and the second opposed wiring portion 72P are not provided.

Note that in FIG. 4, Ls2P represents a self-inductance from one end (third connection point P3) to the other end (fourth connection point P4) of the second capacitor connection wiring 80P, and a parasitic inductance L2P from one end to the other end of the second capacitor connection wiring 80P is the same as the self-inductance Ls2P.

Regarding the relationship between the parasitic inductance and the thermal resistance of the first capacitor connection wiring 70P in the present example and the comparative example, as illustrated in FIG. 5, in the present example, the wiring length DP₁ of the first capacitor connection wiring 70P is increased to increase the thermal resistance, and the parasitic inductance in the first capacitor connection wiring 70P can be made smaller than that in the comparative example after ensuring the thermal resistance necessary for preventing heat reception by the capacitor element 20P.

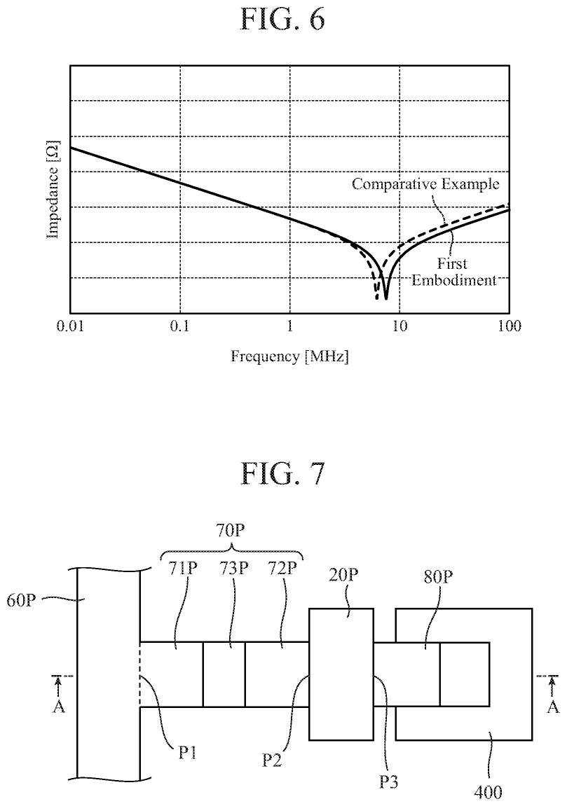

In addition, since the parasitic inductance of the first capacitor connection wiring 70P can be reduced, the high-frequency impedance is reduced as compared with the comparative example as illustrated in FIG. 6, so that the noise absorption effect can be enhanced.

As described above, in the power conversion device according to the first embodiment, the first capacitor connection wiring 70P electrically connected between the positive electrode-side power supply wiring 60P and one electrode of the capacitor element 20P is continuously formed with respect to the positive electrode-side noise-removing capacitor element 20P, the first capacitor connection wiring 70P includes the first opposed wiring portion 71P having one end electrically connected to the positive electrode-side power supply wiring 60P and the second opposed wiring portion 72P having the other end electrically connected to one electrode of the capacitor element 20P, and at least a part of each of the first opposed wiring portion 71P and the second opposed wiring portion 72P is arranged to face each other. Therefore, the power conversion device according to the first embodiment suppresses heat reception of the capacitor element 20P due to heat generated in the power supply wiring 60P, and the parasitic inductance in the first capacitor connection wiring 70P on the positive electrode side can be reduced, and the noise absorption effect by the capacitor element 20P can be enhanced.

In the power conversion device according to the first embodiment, the positive electrode-side power supply wiring 60P and the first capacitor connection wiring are separated, and a side surface of the power supply wiring 60P and one end surface of the first capacitor connection wiring 70P are electrically and mechanically connected by soldering, welding, screwing, or the like. Therefore, thermal resistance is large at the first connection point P1 between the power supply wiring 60P and the first capacitor connection wiring 70P, and heat reception of the capacitor element 20P due to heat generated in the power supply wiring 60P can be further suppressed.

In the power conversion device according to the first embodiment, since the first capacitor connection wiring 70P is constituted by the flat plate-like conductor in which the first opposed wiring portion 71P, the second opposed wiring portion 72P, and the bent wiring portion 73P are integrally formed, the spring action due to the provision of the bent wiring portion 73P can maintain the positional accuracy between the other end of the second opposed wiring portion 72P and the one electrode terminal of the capacitor element 20P at the second connection point P2, and can electrically and mechanically connect the other end of the second opposed wiring portion 72P to the one electrode terminal of the capacitor element 20P by soldering or the like in a state where a pressure is applied to the one electrode terminal of the capacitor element 20P so that the other end of the second opposed wiring portion 72P is pressed to it.

That is, the stress applied to the one electrode terminal of the capacitor element 20P is absorbed by the spring action of the first capacitor connection wiring 70P, and there is no gap between the other end of second opposed wiring portion 72P and the one electrode terminal of the capacitor element 20P, and moreover, the other end of the second opposed wiring portion 72P can be electrically and mechanically connected to the one electrode terminal of the capacitor element 20P while preventing the performance degradation of the capacitor element 20P due to the pressure applied to the capacitor element 20P.

Meanwhile, in the power conversion device according to the first embodiment, the suppression of heat reception to the positive electrode-side noise-removing capacitor element 20P and the reduction of the parasitic inductance in the first capacitor connection wiring 70P electrically connected between the positive electrode-side power supply wiring 60P and one electrode of the capacitor element 20P have been described. However, by configuring the first capacitor connection wiring 70N electrically connected between the negative electrode-side power supply wiring 60N and one electrode of the negative electrode-side noise-removing capacitor element 20N in the same manner as the first capacitor connection wiring 70P, the suppression of heat reception to the capacitor element 20N and the reduction of the parasitic inductance in the first capacitor connection wiring 70N electrically connected between the negative electrode-side power supply wiring 60N and one electrode of the capacitor element 20N can be achieved.

That is, similarly to the first capacitor connection wiring 70P, the first capacitor connection wiring 70N has a structure in which it is formed continuously, it includes a first opposed wiring portion having one end electrically connected to the negative electrode-side power supply wiring 60N and a second opposed wiring portion having the other end electrically connected to one electrode of the capacitor element 20N, and at least a part of each of the first opposed wiring portion and the second opposed wiring portion is arranged to face each other.

Hereinafter, the first capacitor connection wiring 70N will be described.

The negative electrode-side power supply wiring 60N is a power supply wiring electrically connected to the power conversion circuit 10.

The power supply wiring 60N is a flat plate-like conductor having front and back surfaces.

In the power supply wiring 60N, one end is connected to a negative electrode-side input terminal 1N to which the negative electrode of the DC power supply 100 is connected, and the other end is connected to a negative electrode-side input node 11N of the power conversion circuit 10.

The first capacitor connection wiring 70N is electrically connected between the power supply wiring 60N and one electrode of the capacitor element 20N.

The first capacitor connection wiring 70N is a flat plate-like conductor having front and back surfaces.

In the first capacitor connection wiring 70N, one end surface is connected to the side surface of the power supply wiring 60N at the first connection point, and the other end is connected to one electrode terminal connected to one electrode of the capacitor element 20N at the second connection point.

The first capacitor connection wiring 70N includes a first opposed wiring portion having one end electrically connected to the power supply wiring 60N, a second opposed wiring portion having the other end electrically connected to one electrode terminal of the capacitor element 20N and having an opposed portion disposed opposite to an opposed portion of the first opposed wiring, and a bent wiring portion electrically connecting the other end of the first opposed wiring portion and one end of the second opposed wiring portion.

In the first capacitor connection wiring 70N, the first opposed wiring portion, the second opposed wiring portion, and the bent wiring portion are a flat plate-like conductor formed integrally.

One end surface of the first opposed wiring portion is electrically and mechanically connected to the side surface of the power supply wiring 60N at the first connection point by soldering, welding, screwing, or the like.

The first opposed wiring portion has an extending portion extending from one end surface toward one electrode terminal of the capacitor element 20N, and an opposed portion bent from the extending portion at a right angle to the front and back surfaces, on the same plane as the front and back surfaces of the power supply wiring.

The other end of the second opposed wiring portion is electrically and mechanically connected to one electrode terminal of the capacitor element 20N at the second connection point by soldering or the like.

The second opposed wiring portion has an extending portion extending from the other end surface in the direction of the power supply wiring 60N, and an opposed portion bent at a right angle from the extending portion to the front and back surfaces and having a surface facing the surface of the opposed portion in the first opposed wiring portion at equal intervals, on the same plane as the front and back surfaces of the first opposed wiring portion.

The bent wiring portion is continuously formed between the other end of the opposed portion in the first opposed wiring portion and one end of the opposed portion in the second opposed wiring portion.

The front and back surfaces of the bent wiring portion are parallel to the front and back surfaces of the extending portion in the first opposed wiring portion and the front and back surfaces of the extending portion in the second opposed wiring portion 72N.

That is, the first capacitor connection wiring 70N has a structure in which a part thereof is disposed so as to face each other, that is, a structure in which the opposed portion in the first opposed wiring portion and the opposed portion in the second opposed wiring portion are arranged.

The second capacitor connection wiring 80N is electrically connected between the other electrode terminal to which the other electrode of the capacitor element 20N is connected and the metal housing 400.

The second capacitor connection wiring 80N is a flat plate-like conductor having front and back surfaces.

In the second capacitor connection wiring 80N, one end is electrically and mechanically connected to the other electrode terminal of the capacitor element 20N by soldering or the like at the third connection point, and the other end is electrically and mechanically connected to the metal housing 400 by soldering, welding, screwing, or the like at the fourth connection point.

Since the opposed portion in the first opposed wiring portion and the opposed portion in the second opposed wiring portion are provided, the wiring length of the first capacitor connection wiring 70N is longer than the linear distance from the first connection point, which is the connection point between one end face of the first capacitor connection wiring 70N and the side surface of the power supply wiring 60N, to the second connection point, which is the connection point between the other end of the first capacitor connection wiring 70N and one electrode terminal of the capacitor element 20N.

Therefore, since the thermal resistance of the first capacitor connection wiring 70N can be increased, heat generated in the power supply wiring 60N is less likely to be transferred to the capacitor element 20N by the first capacitor connection wiring 70N.

In short, it is possible to suppress heat reception of the capacitor element 20N due to heat generated in the power supply wiring 60N.

In addition, since the first capacitor connection wiring 70N is integrally formed into a flat plate-like conductor having the first opposed wiring portion, the second opposed wiring portion, and the bent wiring portion, when a common mode noise current flows in the first capacitor connection wiring 70N, a current flowing through the first opposed wiring portion and a current flowing through the second opposed wiring portion are in opposite directions. Therefore, due to the mutual inductance M12N by the first opposed wiring portion and the second opposed wiring portion, the parasitic inductance of the present example in which the first opposed wiring portion and the second opposed wiring portion are provided in the first capacitor connection wiring 70N is smaller by (2×M12N) than the parasitic inductance of the comparative example in which the first opposed wiring portion and the second opposed wiring portion are not provided.

Therefore, the parasitic inductance in the negative electrode-side first capacitor connection wiring 70N can be reduced.

In short, similarly to the first capacitor connection wiring 70P, when the first capacitor connection wiring 70N includes the first opposed wiring portion and the second opposed wiring portion, it is possible to suppress heat reception to the negative electrode-side noise-removing capacitor element 20N due to heat generated in the negative electrode-side power supply wiring 60N and to reduce parasitic inductance in the first capacitor connection wiring 70N electrically connected between the negative electrode-side power supply wiring 60N and one electrode of the capacitor element 20N, and to enhance the noise absorption effect by the capacitor element 20N.

In addition, the first capacitor connection wiring 70S electrically connected between the positive electrode-side power supply wiring 60P and one electrode of the smoothing capacitor element 20S has the same configuration as the first capacitor connection wiring 70P, so that it is possible to suppress heat reception to the capacitor element 20S and reduce parasitic inductance in the first capacitor connection wiring 70S electrically connected between the positive electrode-side power supply wiring 60P and one electrode of the capacitor element 20S.

That is, similarly to the first capacitor connection wiring 70P, the first capacitor connection wiring 70S has a structure in which it is formed continuously, it includes the first opposed wiring portion having one end electrically connected to the positive electrode-side power supply wiring 60P and the second opposed wiring portion having the other end electrically connected to one electrode of the capacitor element 20S, and at least a part of each of the first opposed wiring portion and the second opposed wiring portion is arranged to face each other.

Hereinafter, the first capacitor connection wiring 70S will be described.

The first capacitor connection wiring 70S is electrically connected between the power supply wiring 60P and one electrode of the capacitor element 20S.

The first capacitor connection wiring 70S is a flat plate-like conductor having front and back surfaces.

In the first capacitor connection wiring 70S, one end surface is connected to the side surface of the power supply wiring 60P at the first connection point, and the other end is connected to one electrode terminal connected to one electrode of the capacitor element 20S at the second connection point.

The first capacitor connection wiring 70S includes a first opposed wiring portion having one end electrically connected to the power supply wiring 60P, a second opposed wiring portion having the other end electrically connected to one electrode terminal of the capacitor element 20S and having an opposed portion disposed opposite to an opposed portion of the first opposed wiring, and a bent wiring portion electrically connecting the other end of the first opposed wiring portion and one end of the second opposed wiring portion.

In the first capacitor connection wiring 70S, the first opposed wiring portion, the second opposed wiring portion, and the bent wiring portion are a flat plate-like conductor formed integrally.

One end face of the first opposed wiring portion is electrically and mechanically connected to the side surface of the power supply wiring 60P at the first connection point by soldering, welding, screwing, or the like.

The first opposed wiring portion has an extending portion extending from one end surface toward the one electrode terminal of the capacitor element 20S and an opposed portion bent at a right angle from the extending portion to the front and back surfaces, on the same plane as the front and back surfaces of the power supply wiring.

The other end of the second opposed wiring portion is electrically and mechanically connected to one electrode terminal of the capacitor element 20S at the second connection point by soldering or the like.

The second opposed wiring portion has an extending portion extending from the other end surface in the direction of the power supply wiring 60P, and an opposed portion bent at a right angle from the extending portion to the front and back surfaces and having a surface facing a surface of the opposed portion in the first opposed wiring portion at equal intervals, on the same plane as the front and back surfaces of the first opposed wiring portion.

The bent wiring portion is continuously formed between the other end of the opposed portion in the first opposed wiring portion and one end of the opposed portion in the second opposed wiring portion.

The front and back surfaces of the bent wiring portion are parallel to the front and back surfaces of the extending portion in the first opposed wiring portion and the front and back surfaces of the extending portion in the second opposed wiring portion 72N.

That is, the first capacitor connection wiring 70S has a structure in which a part thereof is disposed so as to face each other, that is, a structure in which the opposed portion in the first opposed wiring portion and the opposed portion in the second opposed wiring portion are arranged.

The second capacitor connection wiring 80S is electrically connected between the other electrode terminal to which the other electrode of the capacitor element 20S is connected and the negative electrode-side power supply wiring 60N.

The second capacitor connection wiring 80S is a flat plate-like conductor having front and back surfaces.

In the second capacitor connection wiring 80S, one end is electrically and mechanically connected to the other electrode terminal of the capacitor element 20S by soldering or the like at the third connection point, and the other end surface is electrically and mechanically connected to the side surface of the negative electrode-side power supply wiring 60N by soldering, welding, screwing, or the like at the fourth connection point.

Since the opposed portion in the first opposed wiring portion and the opposed portion in the second opposed wiring portion are provided, the wiring length of the first capacitor connection wiring 70S is longer than the linear distance from the first connection point, which is the connection point between one end surface of the first capacitor connection wiring 70S and the side surface of the power supply wiring 60P, to the second connection point, which is the connection point between the other end of the first capacitor connection wiring 70S and one electrode terminal of the capacitor element 20S.

Therefore, since the thermal resistance of the first capacitor connection wiring 70S can be increased, heat generated in the power supply wiring 60P is less likely to be transferred to the capacitor element 20S by the first capacitor connection wiring 70S.

In short, it is possible to suppress heat reception of the capacitor element 20S due to heat generated in the power supply wiring 60P.

In addition, since the first capacitor connection wiring 70S is integrally formed into a flat plate-like conductor having the first opposed wiring portion, the second opposed wiring portion, and the bent wiring portion, when a normal mode noise current flows in the first capacitor connection wiring 70S, a current flowing through the first opposed wiring portion and a current flowing through the second opposed wiring portion are in opposite directions. Therefore, due to the mutual inductance M12S by the first opposed wiring portion and the second opposed wiring portion, the parasitic inductance of the present example in which the first opposed wiring portion and the second opposed wiring portion are provided in the first capacitor connection wiring 70S is smaller by (2×M12S) than the parasitic inductance of the comparative example in which the first opposed wiring portion and the second opposed wiring portion are not provided.

Therefore, the parasitic inductance in the positive electrode-side first capacitor connection wiring 70S can be reduced.

In short, similarly to the first capacitor connection wiring 70P, when the first capacitor connection wiring 70S includes the first opposed wiring portion and the second opposed wiring portion, it is possible to suppress heat reception to the smoothing capacitor element 20S due to heat generated in the positive electrode-side power supply wiring 60P and to reduce parasitic inductance in the first capacitor connection wiring 70S electrically connected between the positive electrode-side power supply wiring 60P and one electrode of the capacitor element 20S, and to enhance the noise absorption effect by the capacitor element 20S.

Furthermore, the second capacitor connection wiring 80S electrically connected between the negative electrode-side power supply wiring 60N and the other electrode of the smoothing capacitor element 20S is configured to include: a first opposed wiring portion having one end electrically connected to the negative electrode-side power supply wiring 60N; a second opposed wiring portion having the other end electrically connected to the other electrode terminal of the capacitor element 20S and having an opposed portion disposed opposite to the opposed portion of the first opposed wiring; and a bent wiring portion electrically connecting the other end of the first opposed wiring portion and one end of the second opposed wiring portion, and thus it is possible to suppress heat reception to the smoothing capacitor element 20S by heat generated in the negative electrode-side power supply wiring 60N, and to reduce parasitic inductance in the second capacitor connection wiring 80S electrically connected between the negative electrode-side power supply wiring 60N and the other electrode of the capacitor element 20S.

Although not shown in the drawing, in a power conversion device including a capacitor element (X capacitor) that removes a normal mode noise, in which one electrode is connected to the positive electrode-side power supply wiring 60P via a first capacitor connection wiring and the other electrode is connected to a ground node via a second capacitor connection wiring, the first capacitor connection wiring connected to the X capacitor includes: a first opposed wiring portion having one end electrically connected to the positive electrode-side power supply wiring 60P; a second opposed wiring portion having the other end electrically connected to one electrode terminal of the X capacitor and having an opposed portion disposed opposite to an opposed portion of the first opposed wiring; and a bent wiring portion electrically connecting the other end of the first opposed wiring portion and one end of the second opposed wiring portion, and thus it is possible to suppress heat reception to the X capacitor due to heat generated in the positive electrode-side power supply wiring 60P and to reduce parasitic inductance in the first capacitor connection wiring electrically connected between the positive electrode-side power supply wiring 60P and one electrode of the X capacitor.

In addition, although not shown in the drawing, in a power conversion device including a capacitor element (X capacitor) that removes a normal mode noise, in which one electrode is connected to the negative electrode-side power supply wiring 60N via a first capacitor connection wiring and the other electrode is connected to a ground node via a second capacitor connection wiring, the first capacitor connection wiring connected to the X capacitor includes: a first opposed wiring portion having one end electrically connected to the negative electrode-side power supply wiring 60N; a second opposed wiring portion having the other end electrically connected to one electrode terminal of the X capacitor and having an opposed portion disposed opposite to an opposed portion of the first opposed wiring; and a bent wiring portion electrically connecting the other end of the first opposed wiring portion and one end of the second opposed wiring portion, and thus it is possible to suppress heat reception to the X capacitor due to heat generated in the negative electrode-side power supply wiring 60N and to reduce parasitic inductance in the first capacitor connection wiring electrically connected between the negative electrode-side power supply wiring 60N and one electrode of the X capacitor.

### Second Embodiment

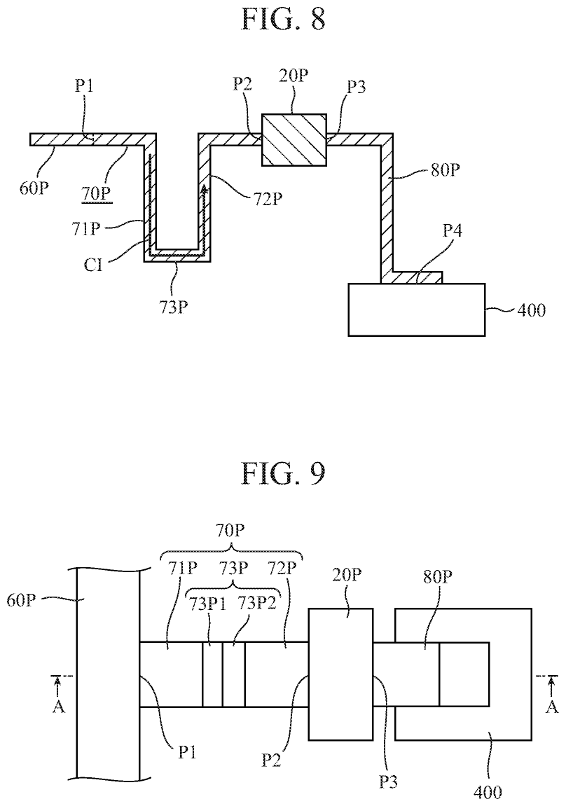

A power conversion device according to a second embodiment will be described with reference to FIGS. 7 and 8.

In the power conversion device according to the first embodiment, in the structure of the electric path from the positive electrode-side power supply wiring 60P to the metal housing 400 serving as the ground node via the positive electrode-side noise-removing capacitor element 20P, the positive electrode-side power supply wiring 60P and the first capacitor connection wiring 70P are separated, and one end surface of the first opposed wiring portion 71P in the first capacitor connection wiring 70P is electrically and mechanically connected to the side surface of the power supply wiring 60P at the first connection point P1 by soldering, welding, screwing, or the like.

On the other hand, in the power conversion device according to the second embodiment, in the structure of the electric path from the positive electrode-side power supply wiring 60P to the metal housing 400 serving as the ground node via the positive electrode-side noise-removing capacitor element 20P, the positive electrode-side power supply wiring 60P and the first capacitor connection wiring 70P are integrally formed, the first capacitor connection wiring 70P is branched from the positive electrode-side power supply wiring 60P on the same plane at the first connection point P1, and the first opposed wiring portion 71P, the second opposed wiring portion 72P, and the bent wiring portion 73P in the first capacitor connection wiring 70P are integrally formed with the power supply wiring 60P.

In other respects, the power conversion device according to the second embodiment is the same as the power conversion device according to the first embodiment.

Note that, in the power conversion device according to the second embodiment, the side surface of the power supply wiring 60P and one end face of the first capacitor connection wiring 70P at the first connection point P1 are not physical boundary surfaces but virtual surfaces.

Similarly to the power conversion device according to the first embodiment, the power conversion device according to the second embodiment can suppress the heat reception of the capacitor element 20P due to the heat generated in the power supply wiring 60P, reduce the parasitic inductance in the positive electrode-side first capacitor connection wiring 70P, and enhance the noise absorption effect by the capacitor element 20P.

Note that in FIGS. 7 and 8, the same reference numerals as those in FIGS. 1 to 4 denote the same or corresponding parts.

In the structure of the electric path from the negative electrode-side power supply wiring 60N to the ground node via the negative electrode-side noise-removing capacitor element 20N shown in the first embodiment, similarly to the above description, the negative electrode-side power supply wiring 60N and the first capacitor connection wiring 70N may be integrally formed.

In the structure of the electric path from the positive electrode-side power supply wiring 60P to the negative electrode-side power supply wiring 60N via the smoothing capacitor element 20S described in the first embodiment, similarly to the above description, the positive electrode-side power supply wiring 60P and the first capacitor connection wiring 70S may be integrally formed, and the negative electrode-side power supply wiring 60N and the second capacitor connection wiring 80S may be integrally formed.

### Third Embodiment

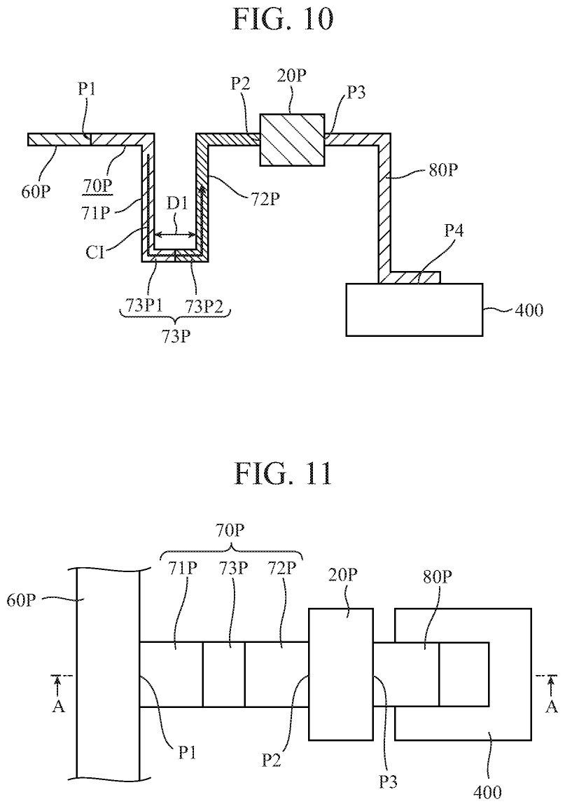

A power conversion device according to a third embodiment will be described with reference to FIGS. 9 and 10.

In the power conversion device according to the first embodiment, in the structure of the electric path from the positive electrode-side power supply wiring 60P to the metal housing 400 serving as the ground node via the positive electrode-side noise-removing capacitor element 20P, the first opposed wiring portion 71P, the second opposed wiring portion 72P, and the bent wiring portion 73P constituting the first capacitor connection wiring 70P are integrally formed.

On the other hand, in the power conversion device according to the third embodiment, the first opposed wiring portion 71P and the second opposed wiring portion 72P in the first capacitor connection wiring 70P are configured as separate components.

In other respects, the power conversion device according to the third embodiment is the same as the power conversion device according to the first embodiment.

Note that in FIGS. 9 and 10, the same reference numerals as those in FIGS. 1 to 4 denote the same or corresponding parts.

In the power conversion device according to the third embodiment, the first capacitor connection wiring 70P is constituted by two connection wirings that are flat plate-like conductors having front and back surfaces divided at the central portion of the bent wiring portion 73P, and the two connection wirings are configured to be electrically and mechanically connected to each other at the central portion of the bent wiring portion 73P with the end surfaces thereof connected by soldering or the like.

That is, the first capacitor connection wiring 70P includes: a connection wiring A having a first opposed wiring portion 71P having one end electrically connected to the power supply wiring 60P and one wiring portion 73P1 of a bent wiring portion 73P formed continuously from the other end of the first opposed wiring portion 71P; and a connection wiring B having a second opposed wiring portion 72P having the other end electrically connected to one electrode terminal of the capacitor element 20P and having an opposed portion disposed opposite to the opposed portion of the first opposed wiring portion 71P and the other wiring portion 73P2 of the bent wiring portion 73P formed continuously from one end of the second opposed wiring portion 72P, and the other end surface of one wiring portion 73P1 of the bent wiring portion 73P and one end surface of the other wiring portion 73P2 of the bent wiring portion 73P are electrically and mechanically connected by soldering or the like.

As a result, the first capacitor connection wiring 70P forms an electric path from the positive electrode-side power supply wiring 60P to one electrode terminal of the capacitor element 20P by a path of the first opposed wiring portion 71P—one wiring portion 73P1 of the bent wiring portion 73P—the other wiring portion 73P2 of the bent wiring portion 73P—the second opposed wiring portion 72P.

Note that, the other end surface of the first opposed wiring portion 71P, one end surface of one wiring portion 73P1 of the bent wiring portion 73P, the other end surface of the second opposed wiring portion 72P, and the other end surface of the other wiring portion 73P2 of the bent wiring portion 73P are not physical boundary surfaces but virtual surfaces.

In this way, since the first capacitor connection wiring 70P is configured by the connection wiring A having the first opposed wiring portion 71P and the connection wiring B having the second opposed wiring portion 72P, there is no restriction on the bending processing when the bent wiring portion 73P is formed. Therefore, the opposed portion of the first opposed wiring portion 71P and the opposed portion of the second opposed wiring portion 72P can be arranged close to each other by shortening the interval D1 between the opposed portion of the first opposed wiring portion 71P and the opposed portion of the second opposed wiring portion 72P.

As a result, the effect of canceling out the magnetic flux generated by the common mode noise current CI at the opposed portion of the first opposed wiring portion 71P and the magnetic flux generated by the common mode noise current CI at the opposed portion of the second opposed wiring portion 72P is enhanced, that is, the mutual inductance M12P of the first opposed wiring portion 71P and the second opposed wiring portion 72P is increased, the parasitic inductance in the first capacitor connection wiring 70P can be further reduced, and the noise absorption effect by the capacitor element 20P can be enhanced.

In addition, since the other end surface of one wiring portion 73P1 of the bent wiring portion 73P and one end surface of the other wiring portion 73P2 of the bent wiring portion 73P are connected by soldering or the like, the thermal resistance at the connection portion can be increased, and the heat reception of the capacitor element 20P due to the heat generated by the power supply wiring 60P can be further suppressed.

As described above, the power conversion device according to the third embodiment has the same effects as those of the power conversion device according to the first embodiment, and has a configuration in which the first opposed wiring portion 71P and the second opposed wiring portion 72P in the first capacitor connection wiring 70P are configured as separate components and are connected to each other. Therefore, it is possible to further suppress the heat reception of the capacitor element 20P due to the heat generated in the power supply wiring 60P, and further reduce the parasitic inductance in the positive electrode-side first capacitor connection wiring 70P to further enhance the noise absorption effect by the capacitor element 20P.

Note that, also in the power conversion device according to the third embodiment, as described in the second embodiment, the positive electrode-side power supply wiring 60P and the first capacitor connection wiring 70P may be integrally formed.

In the structure of the electric path from the negative electrode-side power supply wiring 60N to the ground node via the negative electrode-side noise-removing capacitor element 20N shown in the first embodiment, similarly to the above description, the first capacitor connection wiring 70N may be configured by the connection wirings A and B that are two separate components obtained by dividing the first capacitor connection wiring 70N at the central portion of the bent wiring portion and are flat plate-like conductors having front and back surfaces, the connection wiring A may be configured to have a first opposed wiring portion having one end electrically connected to the power supply wiring 60N and one wiring portion of a bent wiring portion formed continuously from the other end of the first opposed wiring portion, and the connection wiring B may be configured to have a second opposed wiring portion having the other end electrically connected to one electrode terminal of the capacitor element 20N and having an opposed portion disposed opposite to the opposed portion of the first opposed wiring, and the other wiring portion of the bent wiring portion continuously formed from one end of the second opposed wiring portion, and the other end surface of one wiring portion of the bent wiring portion and one end surface of the other wiring portion of the bent wiring portion may be electrically and mechanically connected by soldering or the like.

In addition, in the structure of the electric path from the positive electrode-side power supply wiring 60P to the negative electrode-side power supply wiring 60N via the smoothing capacitor element 20S described in the first embodiment, similarly to the above description, the first capacitor connection wiring 70S may be configured by connection wirings A, B that are two separate components obtained by dividing the first capacitor connection wiring 70S at the central portion of the bent wiring portion and are flat plate-like conductors having front and back surfaces, the connection wiring A may be configured to have a first opposed wiring portion having one end electrically connected to the power supply wiring 60N and one wiring portion of the bent wiring portion formed continuously from the other end of the first opposed wiring portion, and the connection wiring B may be configured to have a second opposed wiring portion having the other end electrically connected to one electrode terminal of the capacitor element 20S and having the opposed portion disposed opposite to the opposed portion of the first opposed wiring, and the other wiring portion of the bent wiring portion continuously formed from one end of the second opposed wiring portion, and the other end surface of one wiring portion of the bent wiring portion and one end surface of the other wiring portion of the bent wiring portion may be electrically and mechanically connected by soldering or the like.

### Fourth Embodiment

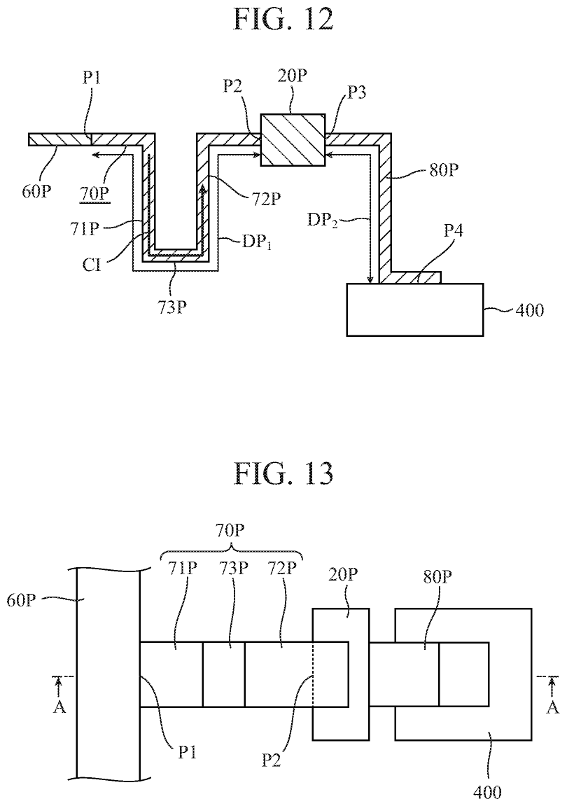

A power conversion device according to a fourth embodiment will be described with reference to FIGS. 11 and 12.

The power conversion device according to the fourth embodiment is characterized in that the length of the second capacitor connection wiring 80P is shorter than the length of the first capacitor connection wiring 70P in the power conversion device according to the first embodiment.

Note that, in FIGS. 11 and 12, the same reference numerals as those in FIGS. 1 to 4 denote the same or corresponding parts.

In the power conversion device according to the fourth embodiment, as illustrated in FIG. 12, a length DP₂ of the second capacitor connection wiring 80P, that is, the length DP₂ of the second capacitor connection wiring 80P from the third connection point P3 connected to the other electrode terminal of the capacitor element 20P to the fourth connection point P4 connected to the metal housing 400 is made shorter than a length DP₁ of the first capacitor connection wiring 70P, that is, the length DP₁ of the first capacitor connection wiring 70P from the first connection point P1 where the first opposed wiring portion 71P is connected to the power supply wiring 60P to the second connection point P2 where the second opposed wiring portion 72P is connected to one electrode terminal of the capacitor element 20P.

As described above, by shortening the length DP₂ of the second capacitor connection wiring 80P, the thermal resistance of the second capacitor connection wiring 80P can be reduced, and the heat generated by the capacitor element 20P can be quickly transferred to the metal housing 400.

As described above, the power conversion device according to the fourth embodiment can suppress the heat reception of the capacitor element 20P due to the heat generated in the power supply wiring 60P, reduce the parasitic inductance in the positive electrode-side first capacitor connection wiring 70P, and enhance the noise absorption effect by the capacitor element 20P, as described in the first embodiment.

Furthermore, since the power conversion device according to the fourth embodiment has a feature that the length of the second capacitor connection wiring 80P is shorter than the length of the first capacitor connection wiring 70P, heat due to self-heating of the capacitor element 20P can be effectively released to the metal housing 400.

Note that, also in the power conversion device according to the fourth embodiment, as described in the second embodiment, the positive electrode-side power supply wiring 60P and the first capacitor connection wiring 70P may be integrally formed.

In addition, also in the power conversion device according to the fourth embodiment, as described in the third embodiment, the first opposed wiring portion 71P and the second opposed wiring portion 72P in the first capacitor connection wiring 70P may be configured as separate components, and may be connected to each other.

In the structure of the electric path from the negative electrode-side power supply wiring 60N to the ground node via the negative electrode-side noise-removing capacitor element 20N shown in the first embodiment, similarly to the above description, the length of the second capacitor connection wiring 80N may be shorter than the length of the first capacitor connection wiring 70N.

### Fifth Embodiment

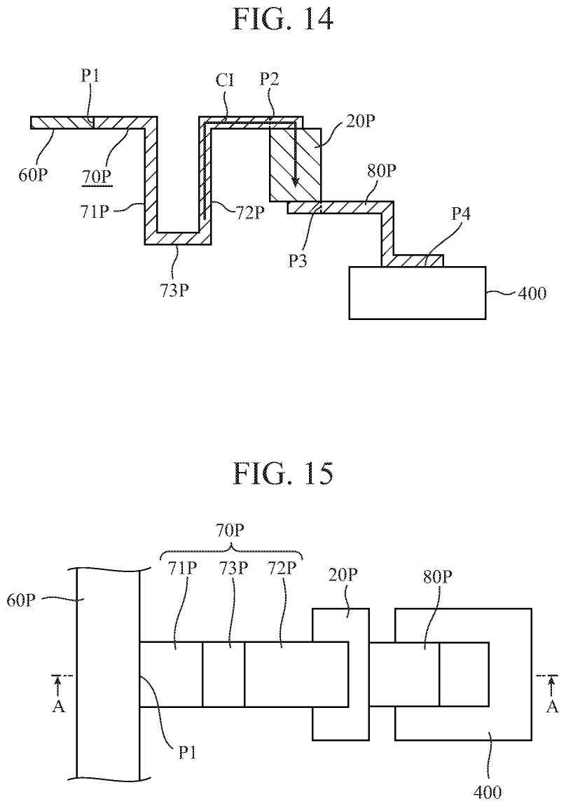

A power conversion device according to a fifth embodiment will be described with reference to FIGS. 13 and 14.

The power conversion device according to the fifth embodiment is characterized by a structure in which, in the power conversion device according to the first embodiment, the first capacitor connection wiring 70P and one electrode of the positive electrode-side noise-removing capacitor element 20P are integrally formed of the same material, or the first capacitor connection wiring 70P and an electrode terminal to which one electrode of the capacitor element 20P is connected are integrally formed of the same material, that is, the first capacitor connection wiring 70P and the capacitor element 20P are integrally formed.

Note that, in FIGS. 13 and 14, the same reference numerals as those in FIGS. 1 to 4 denote the same or corresponding parts.

In the power conversion device according to the fifth embodiment, an electrode terminal to which one electrode of the capacitor element 20P is connected is integrally formed continuously from the other end of the extending portion of the second opposed wiring portion 72P of the first capacitor connection wiring 70P.

The front and back surfaces of the electrode terminal to which one electrode of the capacitor element 20P is connected are positioned on the same plane as the front and back surfaces of the extending portion of the second opposed wiring portion 72P of first capacitor connection wiring 70P.

The other electrode of the capacitor element 20P is disposed opposite to the one electrode and connected to the electrode terminal.

The second capacitor connection wiring 80P may be formed by integrally forming an electrode terminal to which the other electrode of the capacitor element 20P is connected continuously from one end.

Note that, in the power conversion device according to the fifth embodiment, at the second connection point P2, the other end surface of the extending portion of the second opposed wiring portion 72P and the end surface of the one electrode terminal of the capacitor element 20P are not physical boundary surfaces but virtual surfaces.

Note that, also in the power conversion device according to the fifth embodiment, as described in the second embodiment, the positive electrode-side power supply wiring 60P and the first capacitor connection wiring 70P may be integrally formed.

In addition, also in the power conversion device according to the fifth embodiment, as described in the third embodiment, the first opposed wiring portion 71P and the second opposed wiring portion 72P in the first capacitor connection wiring 70P may be configured as separate components, and may be connected to each other.

Furthermore, also in the power conversion device according to the fifth embodiment, as described in the fourth embodiment, the length of the second capacitor connection wiring 80P may be shorter than the length of the first capacitor connection wiring 70P.

In the structure of the electric path from the negative electrode-side power supply wiring 60N to the ground node via the negative electrode-side noise-removing capacitor element 20N shown in the first embodiment, similarly to the above description, the first capacitor connection wiring 70N and the capacitor element 20N may be integrally formed.

In the structure of the electric path from the positive electrode-side power supply wiring 60P to the negative electrode-side power supply wiring 60N via the smoothing capacitor element 20S shown in the first embodiment, similarly to the above description, the first capacitor connection wiring 70S and capacitor element 20S may be integrally formed.

### Sixth Embodiment

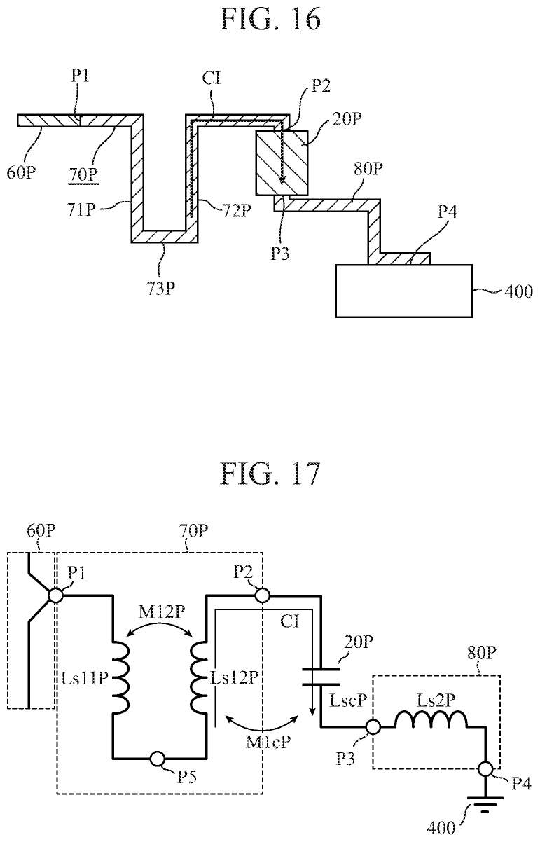

A power conversion device according to a sixth embodiment will be described with reference to FIGS. 15 to 17.

In the power conversion device according to the first embodiment, the direction in which the common mode noise current CI flows through the positive electrode-side noise-removing capacitor element 20P is the same as the direction in which the first capacitor connection wiring 70P extends from the side surface of the power supply wiring 60P.

On the other hand, the power conversion device according to the sixth embodiment has a structure in which the capacitor element 20P, at least a part of the current direction of the common mode noise current CI flowing between the counter electrodes, that is, between one electrode and the other electrode, is disposed to face at least a part of the opposed portion of the opposed wiring portion of at least one of the opposed portion of the first opposed wiring portion 71P and the opposed portion of the second opposed wiring portion 72P of the first capacitor connection wiring 70P.

In other respects, the power conversion device according to the sixth embodiment is the same as the power conversion device according to the first embodiment.

Note that, in FIGS. 15 to 17, the same reference numerals as those in FIGS. 1 to 4 denote the same or corresponding parts.

In the power conversion device according to the sixth embodiment, the capacitor element 20P is disposed with respect to the first capacitor connection wiring 70P in a direction in which the direction in which the common mode noise current CI flows through the capacitor element 20P is orthogonal to the direction in which the first capacitor connection wiring 70P extends from the side surface of the power supply wiring 60P, that is, in a direction parallel to the current direction of the common mode noise current CI flowing through the opposed portion of the first opposed wiring portion 71P and the opposed portion of the second opposed wiring portion 72P of the first capacitor connection wiring 70P, and at a position where a magnetic flux generated by the common mode noise current CI flowing through the opposed portion of the second opposed wiring portion 72P of the first capacitor connection wiring 70P and a magnetic flux generated by the common mode noise current CI flowing through the capacitor element 20P cancel each other.

The front and back surfaces of one electrode of the capacitor element 20P are parallel to the front and back surfaces of the extending portion of the second opposed wiring portion 72P, and the other electrode of the capacitor element 20P is disposed to face one electrode of the capacitor element 20P on the side where the bent wiring portion 73P of the first capacitor connection wiring 70P is positioned.

The common mode noise current CI flowing through the opposed portion of the second opposed wiring portion 72P and the common mode noise current CI flowing through the capacitor element 20P flow in opposite directions to each other, and by shortening the interval between the opposed portion of the second opposed wiring portion 72P and the side surface of the capacitor element 20P parallel to the current direction in which the common mode noise current CI flows in the capacitor element 20P, the magnetic flux generated by the common mode noise current CI flowing through the opposed portion of the second opposed wiring portion 72P and the magnetic flux generated by the common mode noise current CI flowing through the capacitor element 20P cancel each other out.

The parasitic inductance of the first capacitor connection wiring 70P in the electric path from the positive electrode-side power supply wiring 60P to the metal housing 400 serving as the ground node via the positive electrode-side noise-removing capacitor element 20P configured as described above will be described with reference to FIG. 17.

FIG. 17 is an equivalent circuit diagram of an electric path from the power supply wiring 60P to the ground node (metal housing 400) via the capacitor element 20P.

The first parasitic inductance L11P from one end (first connection point P1) of the first opposed wiring portion 71P to the intermediate point P5 of the bent wiring portion 73P in the first capacitor connection wiring 70P is expressed by the above Formula (2).

On the other hand, the second parasitic inductance L12P from the intermediate point P5 of the bent wiring portion 73P to the other end (second connection point P2) of the second opposed wiring portion 72P in the first capacitor connection wiring 70P is expressed by the following Formula (5).

As a result, the parasitic inductance L1P from one end (first connection point P1) to the other end (second connection point P2) in the first capacitor connection wiring 70P is expressed by the following Formula (6).

$$L 12 P = Ls 12 P - M 12 P - M 1 cP \qquad ( 5 )$$

$$\begin{matrix}L 1 P = L 11 P + L 12 P \\ = Ls 11 P + Ls 12 P - 2 \times M 12 P - M 1 cP\end{matrix} \qquad ( 6 )$$

Note that, in Formulae (5) and (6), M1cP is the mutual inductance between the second opposed wiring portion 72P and the capacitor element 20P.

As understood from Formula (6), when the lengths of the first capacitor connection wirings 70P are the same, the parasitic inductance L1P of the present example in which the first opposed wiring portion 71P and the second opposed wiring portion 72P are provided in the first capacitor connection wiring 70P, and the current direction of the common mode noise current CI flowing through the capacitor element 20P is arranged to face at least a part of the opposed portion of the second opposed wiring portion 72P is smaller by (2×M12P+M1cP) than the parasitic inductance of the first capacitor connection wiring in the comparative example in which the first opposed wiring portion 71P and the second opposed wiring portion 72P are not provided.

In addition, the parasitic inductance LcP of the capacitor element 20P can be expressed by the following Formula (7).

LcP=LscP−M1cP (7)

Note that in Formula (7), LscP is the self-inductance of the capacitor element 20P.

As understood from Formula (7), the parasitic inductance LcP of the capacitor element 20P is smaller by M1cP than the parasitic inductance (LscP) of the capacitor element 20P in the example in which the current direction of the common mode noise current CI flowing through the capacitor element 20P is not arranged to face the opposed portion of the second opposed wiring portion 72P.

As a result, the parasitic inductance in the electric path from the power supply wiring 60P to the ground node via the capacitor element 20P can be reduced, the impedance in the electric path with respect to the common mode noise current CI having a high frequency is reduced, and the noise absorption effect can be further enhanced.

As described above, the power conversion device according to the sixth embodiment has the same effects as those of the power conversion device according to the first embodiment, and the capacitor element 20P is disposed to face the opposed portion of the second opposed wiring portion 72P so that the current direction of the common mode noise current CI flowing through the capacitor element 20P faces the opposed portion of the second opposed wiring portion 72P. Therefore, the parasitic inductance in the positive electrode-side first capacitor connection wiring 70P is further reduced, and the parasitic inductance of the capacitor element 20P is also reduced, so that the noise absorption effect by the capacitor element 20P can be further enhanced.

Note that, also in the power conversion device according to the sixth embodiment, as described in the second embodiment, the positive electrode-side power supply wiring 60P and the first capacitor connection wiring 70P may be integrally formed.

In addition, also in the power conversion device according to the sixth embodiment, as described in the third embodiment, the first opposed wiring portion 71P and the second opposed wiring portion 72P in the first capacitor connection wiring 70P may be configured as separate components, and may be connected to each other.

Furthermore, also in the power conversion device according to the sixth embodiment, as described in the fourth embodiment, the length of the second capacitor connection wiring 80P may be shorter than the length of the first capacitor connection wiring 70P.

Furthermore, also in the power conversion device according to the sixth embodiment, as described in the fifth embodiment, a structure in which the first capacitor connection wiring 70P and the capacitor element 20P are integrally formed may be adopted.

In the structure of the electric path from the negative electrode-side power supply wiring 60N to the ground node via the negative electrode-side noise-removing capacitor element 20N shown in the first embodiment, similarly to the above description, the capacitor element 20N may be disposed to face the opposed portion of the second opposed wiring portion so that the current direction of the common mode noise current flowing through the capacitor element 20N faces the opposed portion of the second opposed wiring portion.

In the structure of the electric path from the positive electrode-side power supply wiring 60P to the negative electrode-side power supply wiring 60N via the smoothing capacitor element 20S shown in the first embodiment, similarly to the above description, the capacitor element 20S may be disposed to face the opposed portion of the second opposed wiring portion so that the current direction of the normal mode noise current flowing through the capacitor element 20S faces the opposed portion of the second opposed wiring portion.

### Seventh Embodiment

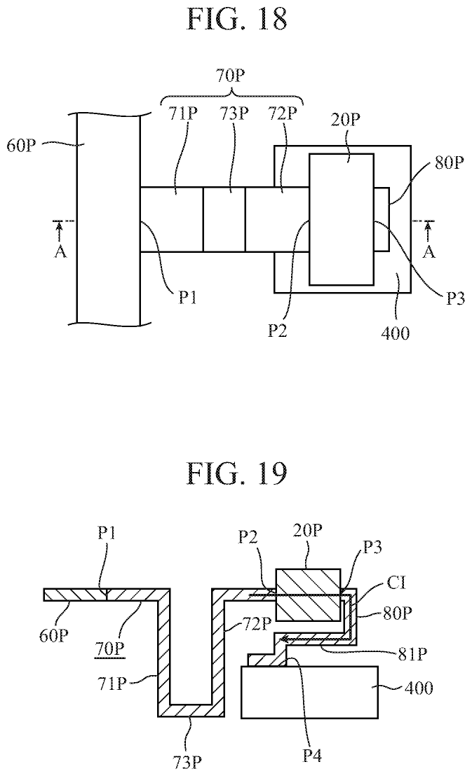

A power conversion device according to a seventh embodiment will be described with reference to FIGS. 18 to 20.

The power conversion device according to the first embodiment has a configuration in which the second capacitor connection wiring 80P is simply electrically connected between the other electrode terminal to which the other electrode of the positive electrode-side noise-removing capacitor element 20P is connected and the metal housing 400.

On the other hand, the power conversion device according to the seventh embodiment has a configuration in which at least a part of the capacitor element 20P is disposed to face at least a part of the second capacitor connection wiring 80P, that is, a configuration in which the current direction of the common mode noise current flowing between one electrode and the other electrode of the capacitor element 20P and the current direction of the common mode noise current flowing through an opposed portion 81P of the second capacitor connection wiring 80P facing the capacitor element 20P are reversed, and the magnetic fluxes generated by the respective common mode noise currents cancel each other out.

In other respects, the power conversion device according to the seventh embodiment is the same as the power conversion device according to the first embodiment.

Note that, in FIGS. 18 to 20, the same reference numerals as those in FIGS. 1 to 4 denote the same or corresponding parts.

In the power conversion device according to the seventh embodiment, the second capacitor connection wiring 80P has the opposed portion 81P disposed facing the capacitor element 20P.

The current direction of the common mode noise current CI flowing through the opposed portion 81P of the second capacitor connection wiring 80P faces at least a part of the current direction of the common mode noise current CI flowing between one electrode and the other electrode in the capacitor element 20P, and the current directions of the common mode noise currents CI are opposite to each other.

The opposed portion 81P of the second capacitor connection wiring 80P and the capacitor element 20P are arranged at a position where the magnetic flux generated by the common mode noise current CI flowing through the opposed portion 81P of the second capacitor connection wiring 80P and the magnetic flux generated by the common mode noise current CI flowing through the capacitor element 20P act to cancel each other.

The second capacitor connection wiring 80P includes a first extending portion having one end electrically and mechanically connected to the other electrode terminal to which the other electrode of the capacitor element 20P is connected at the third connection point P3 by soldering or the like, an opposed portion 81P continues from the other end of the first extending portion, bent at a right angle in the direction of the capacitor element 20P and disposed to face the side surface of the capacitor element 20P parallel to the current direction in which the common mode noise current CI in the capacitor element 20P flows, and a second extending portion continues from the other end of the opposed portion 81P, bent at a right angle in the direction away from the capacitor element 20P and having the other end electrically and mechanically connected to the metal housing 400 by soldering or the like at the fourth connection point P4.

The common mode noise current CI flowing through the opposed portion 81P of the second capacitor connection wiring 80P and the common mode noise current CI flowing through the capacitor element 20P flow in opposite directions to each other, and by shortening the interval between the opposed portion 81P of the second capacitor connection wiring 80P and the side surface of the capacitor element 20P, the magnetic flux generated by the common mode noise current CI flowing through the opposed portion 81P of the second capacitor connection wiring 80P and the magnetic flux generated by the common mode noise current CI flowing through the capacitor element 20P cancel each other.

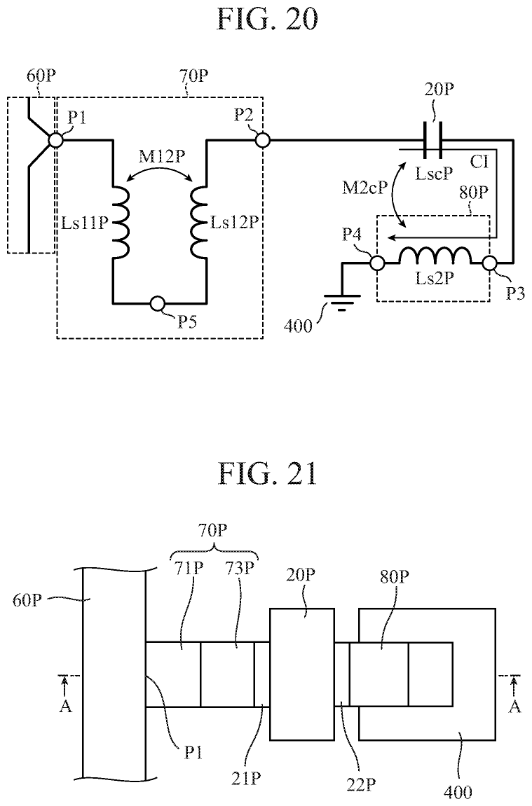

The parasitic inductance of the second capacitor connection wiring 80P in the electric path from the positive electrode-side power supply wiring 60P to the metal housing 400 serving as the ground node via the positive electrode-side noise-removing capacitor element 20P configured as described above will be described with reference to FIG. 20.

FIG. 20 is an equivalent circuit diagram of an electric path from the power supply wiring 60P to the ground node (metal housing 400) via the capacitor element 20P.

The parasitic inductance L2P from one end (third connection point P3) to the other end (fourth connection point P4) of the second capacitor connection wiring 80P is expressed by the following Formula (8).

In addition, the parasitic inductance LcP of the capacitor element 20P is expressed by the following Formula (9).

L2P=Ls2P−M2cP (8)

LcP=LscP−M2cP (9)

Note that, in Formulae (8) and (9), M2cP is a mutual inductance between the opposed portion 81P of the second capacitor connection wiring 80P and the capacitor element 20P.

As understood from Formula (8), the second capacitor connection wiring 80P has the opposed portion 81P facing the current direction of the common mode noise current flowing through the capacitor element 20P and disposed at a position where the magnetic flux generated by the common mode noise current CI that acts to cancel the magnetic flux generated by the common mode noise current CI flowing through the capacitor element 20P is generated, so that the parasitic inductance L2P of the second capacitor connection wiring 80P of the present example is smaller by M2cP than the parasitic inductance Ls2P of the second capacitor connection wiring of the comparative example having no opposed portion.

In addition, as can be understood from Formula (8), the parasitic inductance LcP of the capacitor element 20P of the present example is smaller by M2cP than the parasitic inductance LscP of the capacitor element of the comparative example.

As a result, the parasitic inductance in the electric path from the power supply wiring 60P to the ground node via the capacitor element 20P can be reduced, the impedance in the electric path with respect to the common mode noise current CI having a high frequency is reduced, and the noise absorption effect can be further enhanced.

As described above, the power conversion device according to the seventh embodiment has the same effects as those of the power conversion device according to the first embodiment. In addition, since the opposed portion 81P facing the current direction of the common mode noise current CI flowing through the capacitor element 20P is provided in the second capacitor connection wiring 80P, the parasitic inductance in the second capacitor connection wiring 80P is reduced, and the parasitic inductance of the capacitor element 20P is also reduced. Therefore, the noise absorption effect by the capacitor element 20P can be further enhanced.

Note that, also in the power conversion device according to the seventh embodiment, as described in the second embodiment, the positive electrode-side power supply wiring 60P and the first capacitor connection wiring 70P may be integrally formed.

In addition, also in the power conversion device according to the seventh embodiment, as described in the third embodiment, the first opposed wiring portion 71P and the second opposed wiring portion 72P in the first capacitor connection wiring 70P may be configured as separate components, and may be connected to each other.

Further, also in the power conversion device according to the seventh embodiment, as described in the fourth embodiment, the length of the second capacitor connection wiring 80P may be shorter than the length of the first capacitor connection wiring 70P.

Furthermore, also in the power conversion device according to the seventh embodiment, as described in the fifth embodiment, a structure in which the first capacitor connection wiring 70P and the capacitor element 20P are integrally formed may be adopted.

Furthermore, also in the power conversion device according to the seventh embodiment, as described in the sixth embodiment, the capacitor element 20P may be disposed facing the opposed portion of the second opposed wiring portion 72P so that the current direction of the common mode noise current CI flowing through the capacitor element 20P faces the opposed portion of the second opposed wiring portion 72P in the first capacitor connection wiring 70P.

In the structure of the electric path from the negative electrode-side power supply wiring 60N to the ground node via the negative electrode-side noise-removing capacitor element 20N shown in the first embodiment, similarly to the above description, the opposed portion facing the current direction of the common mode noise current flowing through the capacitor element 20N may be provided in the second capacitor connection wiring 80N.

In the structure of the electric path from the positive electrode-side power supply wiring 60P to the negative electrode-side power supply wiring 60N via the smoothing capacitor element 20S described in the first embodiment, similarly to the above description, an opposed portion facing the current direction of the normal mode noise current flowing through the capacitor element 20S may be provided in the second capacitor connection wiring 80S.

### Eighth Embodiment

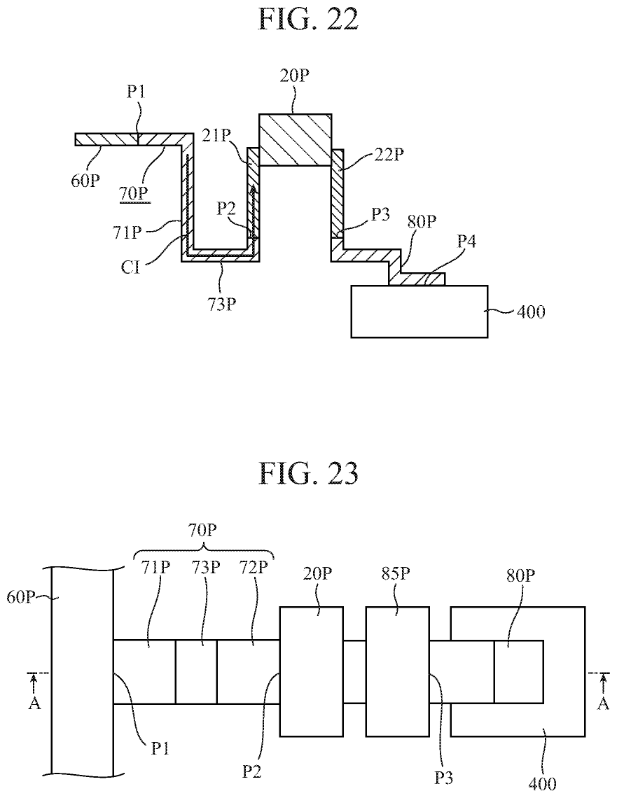

A power conversion device according to an eighth embodiment will be described with reference to FIGS. 21 and 22.

The power conversion device according to the first embodiment has a configuration to include an opposed portion facing the opposed portion of the first opposed wiring portion 71P as the second opposed wiring portion 72P in the first capacitor connection wiring 70P, and an extending portion continuously extending from one end of the opposed portion and having the other end connected to one electrode terminal of the capacitor element 20P at the second connection point P2.

On the other hand, the power conversion device according to the eighth embodiment has a configuration to use, as the capacitor element 20P, a capacitor element including one electrode terminal 21P and the other electrode terminal 22P, each of which is a flat plate-like conductor protruding from the main body in one direction of the main body, in which the surface of the one electrode terminal 21P of the capacitor element is disposed facing the surface of the opposed portion of the first opposed wiring portion 71P, and the distal end surface of the one electrode terminal 21P of the capacitor element 20P is electrically and mechanically connected to the other end surface of the opposed portion of the second opposed wiring portion 72P by soldering, welding, or the like.

The connection point between the distal end surface of one electrode terminal 21P of the capacitor element 20P and the other end surface of the opposed portion of the second opposed wiring portion 72P is the second connection point P2.

Further, a distal end surface of the other electrode terminal 22P of the capacitor element 20P is electrically and mechanically connected to one end surface of the second capacitor connection wiring 80P by soldering, welding, or the like.

The connection point between the distal end surface of the other electrode terminal 22P of the capacitor element 20P and the other end surface of one end surface of the second capacitor connection wiring 80P is the third connection point P3.

In other respects, the power conversion device according to the eighth embodiment is the same as the power conversion device according to the first embodiment.

Note that, in FIGS. 21 and 22, the same reference numerals as those in FIGS. 1 to 4 denote the same or corresponding parts.

In the power conversion device according to the eighth embodiment, the positive electrode-side noise-removing capacitor element 20P includes: a main body having inside one electrode and the other electrode arranged to face each other, and having a pair of side surfaces parallel to each of the one electrode and the other electrode; one electrode terminal 21P electrically connected to the one electrode, positioned on one side surface side of the pair of side surfaces of the main body, and being a flat plate-like conductor protruding from the main body in one direction of the main body; and the other electrode terminal 22P positioned on the other side surface side of the pair of side surfaces of the main body, and being a flat plate-like conductor protruding from the main body in one direction of the main body.

The one electrode terminal 21P and the other electrode terminal 22P protrude in one direction from the main body in parallel so that the back surfaces face each other.

The one direction in which the one electrode terminal 21P and the other electrode terminal 22P protrude is a direction orthogonal to the current direction of the common mode noise current CI flowing between one electrode and the other electrode in the capacitor element 20P.

The first capacitor connection wiring 70P is a flat plate-like conductor, and includes a first opposed wiring portion 71P, a second opposed wiring portion 72P, and a bent wiring portion 73P which are continuously and integrally formed.

One end of the second opposed wiring portion 72P is continued from the other end of the bent wiring portion 73P bent at a right angle in the direction of the capacitor element 20P, and the surface of the second opposed wiring portion 72P has an opposed portion facing the surface of a part of opposed portion positioned on the bent wiring portion 73P side in the first opposed wiring portion 71P.

The surface of one electrode terminal 21P of the capacitor element 20P is disposed facing the surface of the opposed portion of the first opposed wiring portion 71P.

A distal end surface of one electrode terminal 21P of the capacitor element 20P is electrically and mechanically connected to the other end surface of the opposed portion of the second opposed wiring portion 72P by soldering, welding, or the like.

The surface of the opposed portion of the second opposed wiring portion 72P and the surface of one electrode terminal 21P of the capacitor element 20P face the surface of the opposed portion of the first opposed wiring portion 71P at equal intervals.

The common mode noise current CI flowing through the opposed portion of the first opposed wiring portion 71P and the common mode noise current CI flowing through the opposed portion of the second opposed wiring portion 72P and the one electrode terminal 21P of the capacitor element 20P flow in opposite directions to each other, and by shortening the interval between the surface of the opposed portion of the first opposed wiring portion 71P and the surface of the opposed portion of the second opposed wiring portion 72P and the surface of the one electrode terminal 21P of the capacitor element 20P, the magnetic flux generated by the common mode noise current CI flowing through the opposed portion of the first opposed wiring portion 71P and the magnetic flux generated by the common mode noise current CI flowing through the opposed portion of the second opposed wiring portion 72P and the one electrode terminal 21P of the capacitor element 20P cancel each other.

With such a configuration, a substantial wiring length from the first connection point P1 between one end of the first capacitor connection wiring 70P and the power supply wiring 60P to one electrode of the capacitor element 20P is a sum of a length of the first opposed wiring portion 71P, a length of the bent wiring portion 73P, a length of an opposed portion of the second opposed wiring portion 72P, and a length of one electrode terminal 21P of the capacitor element 20P, and is a length substantially equivalent to a length of the first capacitor connection wiring 70P in the power conversion device according to the first embodiment, and a thermal resistance from the first connection point P1 to one electrode of the capacitor element 20P increases.

On the other hand, the parasitic inductance from the first connection point P1 to the one electrode of the capacitor element 20P is a value obtained by subtracting the self-inductance of the opposed portion of the first opposed wiring portion 71P, the opposed portion of the second opposed wiring portion 72P, and to the other end (second connection point P2) of the second opposed wiring portion 72P, and twice the mutual inductance by the one electrode terminal 21P of the capacitor element 20P, from the sum of the first self-inductance from one end (first connection point P1) of the first opposed wiring portion 71P to the intermediate point P5 of the bent wiring portion 73P and the second self-inductance that is the sum of the self-inductance from the intermediate point P5 of the bent wiring portion 73P to the other end (second connection point P2) of the second opposed wiring portion 72P and the self-inductance of the one electrode terminal 21P of the capacitor element 20P.

As described above, the power conversion device according to the eighth embodiment uses, as the capacitor element 20P, the capacitor element including the one electrode terminal 21P and the other electrode terminal 22P that are a flat plate-like conductor, in which the surface of the one electrode terminal 21P of the capacitor element 20P is disposed facing the surface of the opposed portion of the first opposed wiring portion 71P, and the distal end surface of the one electrode terminal 21P of the capacitor element 20P is electrically and mechanically connected to the other end surface of the opposed portion of the second opposed wiring portion 72P. Therefore, it is possible to suppress heat reception of the capacitor element 20P due to heat generated in the power supply wiring 60P, to reduce parasitic inductance from the connection point P1 between the positive electrode-side first capacitor connection wiring 70P and the power supply wiring 60P to the one electrode of the capacitor element 20P, and to enhance the noise absorption effect by the capacitor element 20P.

Note that, although the capacitor element 20P is a capacitor element including one electrode terminal 21P and the other electrode terminal 22P, each of which is a flat plate-like conductor, the capacitor element may be a capacitor element including one electrode terminal 21P and the other electrode terminal 22P each of which is a cylindrical conductor or a prismatic conductor.

Also in the capacitor element including one electrode terminal 21P and the other electrode terminal 22P, each of which is a cylindrical conductor or a prismatic conductor, similarly to the capacitor element including one electrode terminal 21P and the other electrode terminal 22P, each of which is a flat plate-like conductor, one electrode terminal is disposed facing the opposed portion of the first opposed wiring portion 71P, the distal end of the one electrode terminal is electrically and mechanically connected to the other end of the opposed portion of the second opposed wiring portion 72P by soldering, welding, or the like, and the one electrode terminal and the opposed portion of the second opposed wiring portion 72P face the opposed portion of the first opposed wiring portion 71P at equal intervals.

Note that, also in the power conversion device according to the eighth embodiment, as described in the second embodiment, the positive electrode-side power supply wiring 60P and the first capacitor connection wiring 70P may be integrally formed.

In addition, also in the power conversion device according to the eighth embodiment, as described in the fourth embodiment, the length of the second capacitor connection wiring 80P may be shorter than the sum of the length of the first capacitor connection wiring 70P and the length of the one electrode terminal 21P of the capacitor element 20P.

In the structure of the electric path from the negative electrode-side power supply wiring 60N to the ground node via the negative electrode-side noise-removing capacitor element 20N shown in the first embodiment, similarly to the above description, the capacitor element 20N including one electrode terminal and the other electrode terminal, each of which is a flat plate-like conductor protruding from the main body in one direction of the main body, may be used as the capacitor element 20N, the surface of the one electrode terminal of the capacitor element 20N may be disposed facing the surface of the opposed portion of the first opposed wiring portion of the first capacitor connection wiring 70N, and the distal end surface of the one electrode terminal of the capacitor element 20N may be electrically and mechanically connected to the other end surface of the opposed portion of the second opposed wiring portion 72N of the first capacitor connection wiring 70N.

In addition, in the structure of the electric path from the positive electrode-side power supply wiring 60P to the negative electrode-side power supply wiring 60N via the smoothing capacitor element 20S shown in the first embodiment, similarly to the above description, the capacitor element 20S including one electrode terminal and the other electrode terminal, each of which is a flat plate-like conductor protruding from the main body in one direction of the main body, may be used as the capacitor element 20S, the surface of one electrode terminal of the capacitor element 20S may be disposed facing the surface of the opposed portion of the first opposed wiring portion of the first capacitor connection wiring 70S, and the distal end surface of the one electrode terminal of the capacitor element 20S may be electrically and mechanically connected to the other end surface of the opposed portion of the second opposed wiring portion 72S of the first capacitor connection wiring 70S.

### Ninth Embodiment

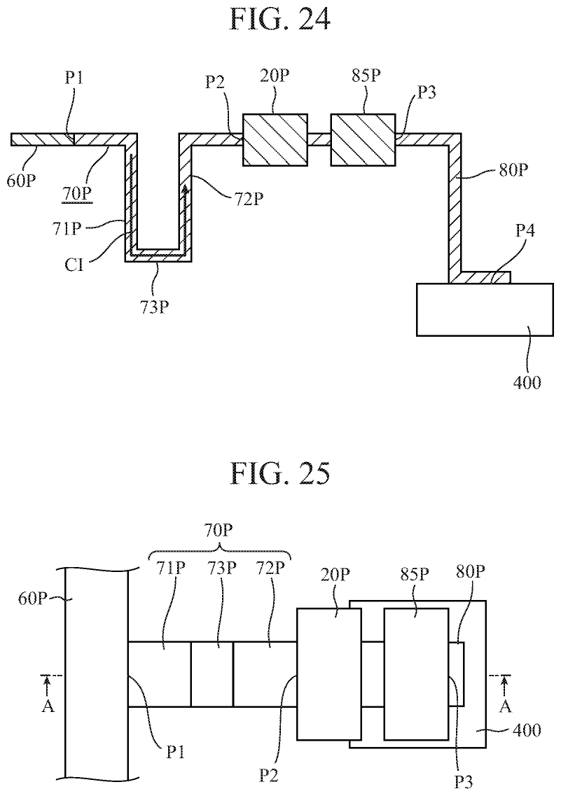

A power conversion device according to a ninth embodiment will be described with reference to FIGS. 23 and 24.

The power conversion device according to the ninth embodiment further includes a resistance element 85P electrically connected in series to the capacitor element 20P as compared with the power conversion device according to the first embodiment.

In other respects, the power conversion device according to the ninth embodiment is the same as the power conversion device according to the first embodiment.

Note that, in FIGS. 23 and 24, the same reference numerals as those in FIGS. 1 to 4 denote the same or corresponding parts.

The power conversion device according to the ninth embodiment includes the resistance element 85P electrically connected between the other electrode terminal to which the other electrode of the positive electrode-side noise-removing capacitor element 20P is connected and one end (third connection point P3) of the second capacitor connection wiring 80P.

The resistance element 85P is a snubber resistor constituting an RC snubber circuit that cooperates with the capacitor element 20P and suppresses ringing occurring due to the switching operation of the semiconductor switching element groups 13u, 14u, 13v, 14v, 13w, and 14w in the power conversion circuit 10.

The resistance element 85P reduces the common mode noise by converting the common mode noise current flowing through the capacitor element 20P into heat.

As described above, although heat is applied to the capacitor element 20P by self-heating of the resistance element 85P, the wiring length of the first capacitor connection wiring 70P is increased, and the thermal resistance of the first capacitor connection wiring 70P is increased. Therefore, even in a power conversion device including the resistance element 85P connected in series to the capacitor element 20P, heat reception of the capacitor element 20P due to heat generated by the power supply wiring 60P is suppressed, and thus, the function as the noise-removing capacitor element 20P is not deteriorated.

As described above, in the power conversion device according to the ninth embodiment in which the resistance element 85P connected in series to the capacitor element 20P is provided and the ringing occurring due to the switching operation of the semiconductor switching element groups 13u, 14u, 13v, 14v, 13w, and 14w in the power conversion circuit 10 is suppressed, the heat reception of the capacitor element 20P due to the heat generated in the power supply wiring 60P can be suppressed, the parasitic inductance in the positive electrode-side first capacitor connection wiring 70P can be reduced, and the noise absorption effect by the capacitor element 20P can be enhanced.

Note that, also in the power conversion device according to the ninth embodiment, as shown in the second embodiment, the positive electrode-side power supply wiring 60P and the first capacitor connection wiring 70P may be integrally formed.

In addition, also in the power conversion device according to the ninth embodiment, as shown in the third embodiment, the first opposed wiring portion 71P and the second opposed wiring portion 72P in the first capacitor connection wiring 70P may be configured as separate components, and may be connected to each other.

Further, also in the power conversion device according to the ninth embodiment, as shown in the fourth embodiment, the length of the second capacitor connection wiring 80P may be shorter than the length of the first capacitor connection wiring 70P.

Furthermore, also in the power conversion device according to the ninth embodiment, as shown in the fifth embodiment, a structure in which the first capacitor connection wiring 70P and the capacitor element 20P are integrally formed may be adopted.

Also in the power conversion device according to the ninth embodiment, as shown in the sixth embodiment, the capacitor element 20P may be disposed facing the opposed portion of the second opposed wiring portion 72P so that the current direction of the common mode noise current CI flowing through the capacitor element 20P faces the opposed portion of the second opposed wiring portion 72P in the first capacitor connection wiring 70P.

Also in the power conversion device according to the ninth embodiment, as shown in the seventh embodiment, an opposed portion facing the current direction of the common mode noise current CI flowing through the capacitor element 20P may be provided in the second capacitor connection wiring 80P.

Also in the power conversion device according to the ninth embodiment, as shown in the eighth embodiment, a capacitor element including one electrode terminal 21P and the other electrode terminal 22P that are a flat plate-like conductor may be used as the capacitor element 20P, the surface of one electrode terminal 21P of the capacitor element 20P may be disposed facing the surface of the opposed portion of the first opposed wiring portion 71P of the first capacitor connection wiring 70P, and the distal end surface of one electrode terminal 21P of the capacitor element 20P may be electrically and mechanically connected to the other end surface of the opposed portion of the second opposed wiring portion 72P of the first capacitor connection wiring 70P.

In the structure of the electric path from the negative electrode-side power supply wiring 60N to the ground node via the negative electrode-side noise-removing capacitor element 20N shown in the first embodiment, similarly to the above description, a resistance element electrically connected in series to the capacitor element 20N may be provided.

In addition, in the structure of the electric path from the positive electrode-side power supply wiring 60P to the negative electrode-side power supply wiring 60N via the smoothing capacitor element 20S shown in the first embodiment, similarly to the above description, a resistance element electrically connected in series to the capacitor element 20S may be provided.

### Tenth Embodiment

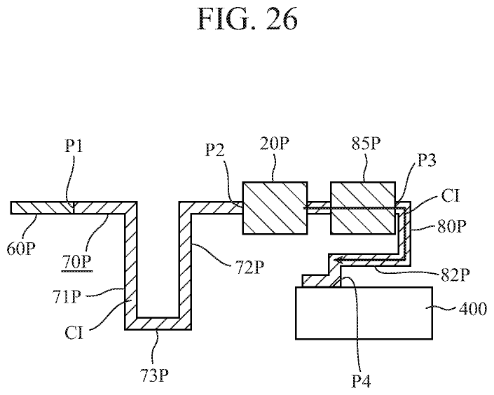

A power conversion device according to a tenth embodiment will be described with reference to FIGS. 25 and 26.

The power conversion device according to the ninth embodiment has a configuration in which the second capacitor connection wiring 80P is simply electrically connected between the resistance element 85P connected to the other electrode terminal to which the other electrode of the positive electrode-side noise-removing capacitor element 20P is connected and the metal housing 400.

On the other hand, the power conversion device according to the tenth embodiment has a configuration in which at least a part of the resistance element 85P is disposed to face at least one component of the first opposed wiring portion 71P and the second opposed wiring portion 72P of the positive electrode-side first capacitor connection wiring 70P, the positive electrode-side noise-removing capacitor element 20P, and the positive electrode-side second capacitor connection wiring 80P in which the common mode noise current CI has a relationship in mutually opposite directions.

In other respects, the power conversion device according to the tenth embodiment is the same as the power conversion device according to the ninth embodiment.

Note that, in FIGS. 25 and 26, the same reference numerals as those in FIGS. 1 to 4 and FIGS. 23 and 24 denote the same or corresponding parts.

Hereinafter, a power conversion device according to the tenth embodiment in which the resistance element 85P is disposed to face the second capacitor connection wiring 80P will be described.

The power conversion device according to the tenth embodiment has a configuration in which the resistance element 85P is disposed facing at least a part of the second capacitor connection wiring 80P, that is, a configuration in which the current direction of the common mode noise current flowing through the resistance element 85P and the current direction of the common mode noise current flowing through the opposed portion 82P of the second capacitor connection wiring 80P facing the resistance element 85P are opposite to each other, and the magnetic fluxes generated by the respective common mode noise currents act to cancel each other.

In the power conversion device according to the tenth embodiment, the second capacitor connection wiring 80P has the opposed portion 81P disposed facing the resistance element 85P.

The current direction of the common mode noise current CI flowing through the opposed portion 81P of the second capacitor connection wiring 80P faces at least a part of the current direction of the common mode noise current CI flowing through the resistance element 85P, and the current directions of the common mode noise currents CI are opposite to each other out.

The opposed portion 81P of the second capacitor connection wiring 80P and the capacitor element 20P are arranged at a position where the magnetic flux generated by the common mode noise current CI flowing through the opposed portion 81P of the second capacitor connection wiring 80P and the magnetic flux generated by the common mode noise current CI flowing through the resistance element 85P act to cancel each other out.

The second capacitor connection wiring 80P includes: a first extending portion having one end electrically and mechanically connected to the other end of the resistance element 85P with one end connected to the other electrode terminal to which the other electrode of the capacitor element 20P is connected at the third connection point P3 by soldering or the like; an opposed portion 82P continues from the other end of the first extending portion bent at a right angle in the direction of the resistance element 85P and disposed to face a side surface of the resistance element 85P parallel to the current direction in which the common mode noise current CI flows in the resistance element 85P; and a second extending portion continuous from the other end of the opposed portion 82P bent at a right angle in a direction away from the resistance element 85P, and having the other end electrically and mechanically connected to the metal housing 400 by soldering or the like at the fourth connection point P4.

The common mode noise current CI flowing through the opposed portion 82P of the second capacitor connection wiring 80P and the common mode noise current CI flowing through the resistance element 85P flow in opposite directions to each other, and the magnetic flux generated by the common mode noise current CI flowing through the opposed portion 81P of the second capacitor connection wiring 80P and the magnetic flux generated by the common mode noise current CI flowing through the resistance element 85P cancel each other out by shortening the interval between the opposed portion 82P of the second capacitor connection wiring 80P and the side surface of the resistance element 85P.

The parasitic inductance of the second capacitor connection wiring 80P in the electric path from the positive electrode-side power supply wiring 60P to the metal housing 400 serving as the ground node via the positive electrode-side noise-removing capacitor element 20P configured as described above is reduced by mutual inductance between the opposed portion 82P of the second capacitor connection wiring 80P and the resistance element 85P.

In addition, the parasitic inductance of the resistance element 85P is also reduced by mutual inductance between the opposed portion 82P of the second capacitor connection wiring 80P and the resistance element 85P.

As a result, the parasitic inductance in the electric path from the power supply wiring 60P to the ground node via the capacitor element 20P can be reduced, the impedance in the electric path with respect to the common mode noise current CI having a high frequency is reduced, and the noise absorption effect can be further enhanced.

As described above, the power conversion device according to the tenth embodiment has the same effects as those of the power conversion device according to the ninth embodiment, and further, since the opposed portion 82P facing the current direction of the common mode noise current CI flowing through the resistance element 85P is provided in the second capacitor connection wiring 80P, the parasitic inductance in the second capacitor connection wiring 80P is reduced, and the parasitic inductance of the resistance element 85P is also reduced, so that the noise absorption effect by the capacitor element 20P can be further enhanced.

Note that, in the power conversion device according to the tenth embodiment, the resistance element 85P is not limited to the configuration in which the resistance element 85P is disposed to face the opposed portion 82P of the second capacitor connection wiring 80P, and the resistance element 85P may be disposed to face at least one component of the opposed portion of the first opposed wiring portion 71P and the opposed portion of the second opposed wiring portion 72P of the first capacitor connection wiring 70P, and the capacitor element 20P through which the common mode noise current CI flows in the opposite direction to the common mode noise current CI flowing through the resistance element 85P.

In the structure of the electric path from the negative electrode-side power supply wiring 60N to the ground node via the negative electrode-side noise-removing capacitor element 20N shown in the ninth embodiment, similarly to the above description, at least a part of the resistance element 85P may be disposed facing at least a part of the second capacitor connection wiring 80P.

In addition, in the structure of the electric path from the positive electrode-side power supply wiring 60P to the negative electrode-side power supply wiring 60N via the smoothing capacitor element 20S shown in the ninth embodiment, similarly to the above description, at least a part of the resistance element 85P may be disposed facing at least a part of the second capacitor connection wiring 80P.

### Eleventh Embodiment

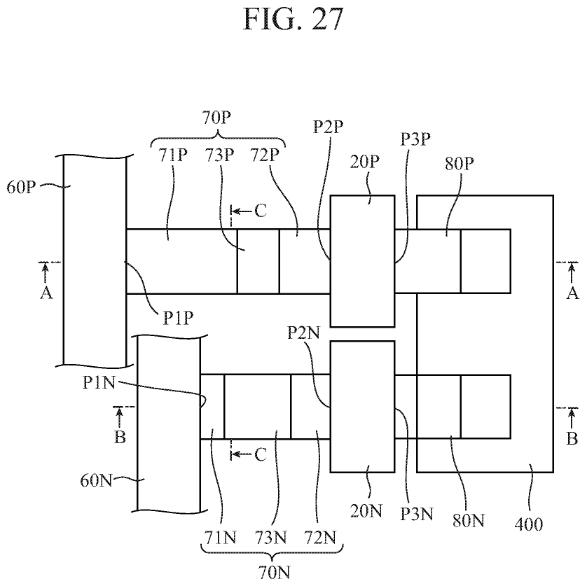

A power conversion device according to an eleventh embodiment will be described with reference to FIGS. 27 to 30.

The power conversion device according to the eleventh embodiment has a configuration in which with respect to the positive electrode-side first capacitor connection wiring 70P, the positive electrode-side noise-removing capacitor element 20P, the positive electrode-side second capacitor connection wiring 80P, the negative electrode-side first capacitor connection wiring 70N, the negative electrode-side noise-removing capacitor element 20N, and the negative electrode-side second capacitor connection wiring 80N described in the first embodiment, in at least one positive electrode-side component and at least one negative electrode-side component, a positive electrode side component and a negative electrode-side component in which the positive electrode-side common mode noise current CIP and the negative electrode-side common mode noise current CIN are opposite to each other are arranged to face each other.

In other respects, the power conversion device according to the eleventh embodiment is the same as the power conversion device according to the first embodiment.

Note that, in FIGS. 27 to 30, the same reference numerals as those in FIGS. 1 to 4 denote the same or corresponding parts.

A structure of an electric path from the positive electrode-side power supply wiring 60P to the metal housing 400 serving as a ground node via the positive electrode-side noise-removing capacitor element 20P, and a structure of an electric path from the negative electrode-side power supply wiring 60N to the metal housing 400 via the negative electrode-side noise-removing capacitor element 20N, which are characteristics of the power conversion device according to the eleventh embodiment, and particularly, an arrangement relationship between both will be mainly described.

The positive electrode-side power supply wiring 60P and the negative electrode-side power supply wiring 60N are arranged in parallel at intervals in the vertical direction and the horizontal direction.

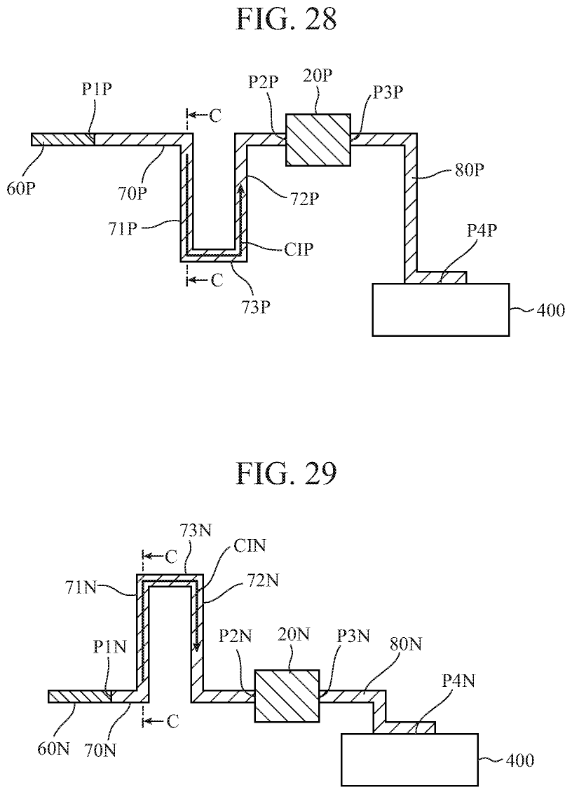

Note that the vertical direction is a direction connecting the front and back surfaces of the power supply wiring 60P and the front and back surfaces of the power supply wiring 60N, respectively, and the vertical direction in FIGS. 28 and 29. The horizontal direction is a direction orthogonal to the vertical direction and the extending direction of the power supply wiring 60P and the negative electrode-side power supply wiring 60N, and the horizontal direction in FIGS. 28 to 30 for convenience.

Further, the longitudinal direction is an extending direction of the power supply wiring 60P and the negative electrode-side power supply wiring 60N, and the vertical direction in FIG. 29 for convenience.

In the following description, in order to eliminate complexity of the description, the description will be made using the vertical direction, the horizontal direction, and the longitudinal direction defined above.

As illustrated in FIGS. 27 and 28, the positive electrode-side first capacitor connection wiring 70P includes: a first opposed wiring portion 71P having one end electrically connected to the positive electrode-side power supply wiring 60P at a first connection point PIP; a second opposed wiring portion 72P having the other end electrically connected to one electrode terminal of the positive electrode-side capacitor element 20P at a second connection point P2P and having an opposed portion disposed facing the opposed portion of the first opposed wiring portion 71P in the horizontal direction; and a bent wiring portion 73P electrically connecting the other end of the first opposed wiring portion 71P and one end of the second opposed wiring portion 72b.

The first opposed wiring portion 71P, the second opposed wiring portion 72P, and the bent wiring portion 73P are a flat plate-like conductor formed integrally.

One end surface of the first opposed wiring portion 71P is electrically and mechanically connected to a side surface of the power supply wiring 60P at the first connection point PlP by soldering, welding, screwing, or the like.

The first opposed wiring portion 71P has an extending portion extending from one end surface connected to the side surface of the power supply wiring 60P at the first connection point PlP in a direction to one electrode terminal of the capacitor element 20P, that is, in the right direction, and an opposed portion bent at a right angle from the extending portion in a direction away from the side surface of the power supply wiring 60P with respect to the front and back surfaces, that is, in the downward direction, on the same plane as the front and back surfaces of the power supply wiring 60P.

The other end of the second opposed wiring portion 72P is electrically and mechanically connected to one electrode terminal of the capacitor element 20P at the second connection point P2P by soldering or the like.

The second opposed wiring portion 72P has an extending portion extending from the other end connected to one electrode terminal of the capacitor element 20P at the second connection point P2P in a direction to the power supply wiring 60P, that is, in the left direction, and an opposed portion bent at a right angle from the extending portion in a direction away from the capacitor element 20P with respect to the front and back surfaces, that is, in the downward direction, and has a surface facing the surface of the opposed portion of the first opposed wiring portion 71P at equal intervals, on the same plane as the front and back surfaces of the first opposed wiring portion 71P

The bent wiring portion 73P is continuously formed between the other end of the opposed portion in the first opposed wiring portion 71P and one end of the opposed portion in the second opposed wiring portion 72P.

The front and back surfaces of the bent wiring portion 73P are parallel to the front and back surfaces of the extending portion in the first opposed wiring portion 71P and the front and back surfaces of the extending portion in the second opposed wiring portion 72P, and are on the same horizontal plane as the front and back surfaces of the power supply wiring 60N.

Note that, although the bent wiring portion 73P is a flat surface, the bent wiring portion 73P may be a curved surface, and an entire shape of the first capacitor connection wiring 70P may be a U-shape in FIG. 28.

That is, the first capacitor connection wiring 70P only needs to have a structure in which the first opposed wiring portion 71P and the second opposed wiring portion 72P are continuously formed, that is, integrally formed, and the opposed portion in the first opposed wiring portion 71P and the opposed portion in the second opposed wiring portion 72P are arranged facing each other in parallel.

The positive electrode-side second capacitor connection wiring 80P has one end electrically and mechanically connected to the other electrode terminal of the capacitor element 20P at a third connection point P3P by soldering or the like, and the other end electrically and mechanically connected to the metal housing 400 at a fourth connection point P4P by soldering, welding, screwing, or the like.

As illustrated in FIGS. 27 and 29, the negative electrode-side first capacitor connection wiring 70N includes: a first opposed wiring portion 71N having one end electrically connected to the negative electrode-side power supply wiring 60N at a first connection point P1N; a second opposed wiring portion 72N having the other end electrically connected to one electrode terminal of the negative electrode-side capacitor element 20N at a second connection point P2N and having an opposed portion disposed facing the opposed portion of the first opposed wiring portion 71N in the horizontal direction; and a bent wiring portion 73N electrically connecting the other end of the first opposed wiring portion 71N and one end of the second opposed wiring portion 72b.

The first opposed wiring portion 71N, the second opposed wiring portion 72N, and the bent wiring portion 73N are a flat plate-like conductor formed integrally.

One end surface of the first opposed wiring portion 71N is electrically and mechanically connected to a side surface of the power supply wiring 60N at the first connection point PIN by soldering, welding, screwing, or the like.

The first opposed wiring portion 71N has an extending portion extending in a direction from one end surface connected to the side surface of the power supply wiring 60N to one electrode terminal of the capacitor element 20N at the first connection point PIN, that is, in the right direction, and an opposed portion bent at a right angle from the extending portion in a direction away from the side surface of the power supply wiring 60N with respect to the front and back surfaces, that is, in the upward direction, on the same plane as the front and back surfaces of the power supply wiring 60N.

The opposed portion of the first opposed wiring portion 71N is disposed facing the opposed portion of the first opposed wiring portion 71P in the positive electrode-side first capacitor connection wiring 70P in the longitudinal direction.

The length of the opposed portion of the first opposed wiring portion 71N is the same as the length of the opposed portion of the first opposed wiring portion 71P.

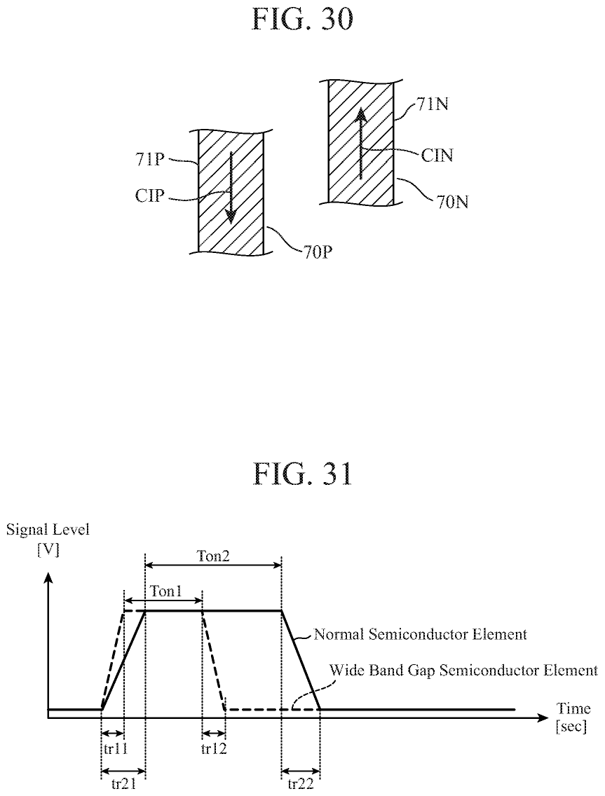

As illustrated in FIG. 30, the common mode noise current CIP flowing through the opposed portion of the first opposed wiring portion 71P in the positive electrode-side first capacitor connection wiring 70P and the common mode noise current CIN flowing through the opposed portion of the first opposed wiring portion 71N in the negative electrode-side first capacitor connection wiring 70N are in opposite directions.

Therefore, the opposed portion of the first opposed wiring portion 71N of the first capacitor connection wiring 70N is disposed with respect to the opposed portion of the second opposed wiring portion 72P of the first capacitor connection wiring 70P at a position where the magnetic flux generated by the common mode noise current CIN flowing through the opposed portion of the first opposed wiring portion 71N of the first capacitor connection wiring 70N and the magnetic flux generated by the common mode noise current CIP flowing through the opposed portion of the second opposed wiring portion 72P of the first capacitor connection wiring 70P act to cancel each other out.

The other end of the second opposed wiring portion 72N is electrically and mechanically connected to one electrode terminal of the capacitor element 20N by soldering or the like at the second connection point P2N.

The second opposed wiring portion 72N has an extending portion extending from the other end connected to one electrode terminal of the capacitor element 20N at the second connection point P2N in a direction to the power supply wiring 60N, that is, in the left direction, and an opposed portion bent at a right angle from the extending portion in a direction away from the capacitor element 20N with respect to the front and back surfaces, that is, in the upward direction, and having a surface facing the surface of the opposed portion of the first opposed wiring portion 71N at equal intervals, on the same plane as the front and back surfaces of the first opposed wiring portion 71N.

The opposed portion of the second opposed wiring portion 72N is disposed facing the opposed portion of the second opposed wiring portion 72P in the positive electrode-side first capacitor connection wiring 70P in the longitudinal direction.

The length of the opposed portion of the second opposed wiring portion 72N is the same as the length of the opposed portion of the second opposed wiring portion 72P.

The common mode noise current CIP flowing through the opposed portion of the second opposed wiring portion 72P in the positive electrode-side first capacitor connection wiring 70P and the common mode noise current CIN flowing through the opposed portion of the second opposed wiring portion 72N of the negative electrode-side first capacitor connection wiring 70N are in opposite directions.

Therefore, the opposed portion of the second opposed wiring portion 72N of the first capacitor connection wiring 70N is disposed with respect to the opposed portion of the second opposed wiring portion 72P of the first capacitor connection wiring 70P at a position where the magnetic flux generated by the common mode noise current CIN flowing through the opposed portion of the second opposed wiring portion 72N of the first capacitor connection wiring 70N and the magnetic flux generated by the common mode noise current CIP flowing through the opposed portion of the second opposed wiring portion 72P of the first capacitor connection wiring 70P act to cancel each other out.

The bent wiring portion 73N is continuously formed between the other end of the opposed portion of the first opposed wiring portion 71N and one end of the opposed portion of the second opposed wiring portion 72N.

The front and back surfaces of the bent wiring portion 73N are parallel to the front and back surfaces of the extending portion of the first opposed wiring portion 71N and the front and back surfaces of the extending portion of the second opposed wiring portion 72N, and are on the same horizontal plane as the front and back surfaces of the power supply wiring 60P.

Note that, although the bent wiring portion 73N is a flat surface, the bent wiring portion 73N may be a curved surface, and an entire shape of the first capacitor connection wiring 70N may be a U-shape in FIG. 29.

That is, the first capacitor connection wiring 70N may have a structure in which the first opposed wiring portion 71N and the second opposed wiring portion 72N are continuously formed, that is, integrally formed, and the opposed portion of the first opposed wiring portion 71N and the opposed portion of the second opposed wiring portion 72N are arranged facing each other in parallel, and the opposed portion of the first opposed wiring portion 71N may be disposed facing the opposed portion of the first opposed wiring portion 71P in parallel, and the opposed portion of the second opposed wiring portion 72N may be disposed facing the opposed portion of the second opposed wiring portion 72P.

The negative electrode-side second capacitor connection wiring 80N has one end electrically and mechanically connected to the other electrode terminal of the capacitor element 20N by soldering or the like at a third connection point P3N, and the other end electrically and mechanically connected to the metal housing 400 by soldering, welding, screwing, or the like at a fourth connection point P4.

The parasitic inductance of the positive electrode-side first capacitor connection wiring 70P in the electric path from the positive electrode-side power supply wiring 60P to the metal housing 400 serving as the ground node via the positive electrode-side noise-removing capacitor element 20P is further reduced by mutual inductance due to the opposed portion of the first opposed wiring portion 71P and the opposed portion of the first opposed wiring portion 71N and mutual inductance due to the opposed portion of the second opposed wiring portion 72P and the opposed portion of the second opposed wiring portion 72N.

Similarly, the parasitic inductance of the negative electrode-side first capacitor connection wiring 70N in the electric path from the negative electrode-side power supply wiring 60N to the metal housing 400 serving as the ground node via the negative electrode-side noise-removing capacitor element 20N is further reduced by the mutual inductance due to the opposed portion of the first opposed wiring portion 71N and the opposed portion of the first opposed wiring portion 71P and the mutual inductance due to the opposed portion of the second opposed wiring portion 72N and the opposed portion of the second opposed wiring portion 72P.

As described above, in the power conversion device according to the eleventh embodiment, since the first capacitor connection wiring 70P electrically connected between the positive electrode-side power supply wiring 60P and one electrode of the positive electrode-side noise-removing capacitor element 20P has the first opposed wiring portion 71P and the second opposed wiring portion 72P with the opposed portions facing each other, it is possible to suppress heat reception of the capacitor element 20P due to heat generated in the power supply wiring 60P, reduce parasitic inductance in the positive electrode-side first capacitor connection wiring 70P, and since the first capacitor connection wiring 70N electrically connected between the negative electrode-side power supply wiring 60N and one electrode of the negative electrode-side noise-removing capacitor element 20N has the first opposed wiring portion 71N and the second opposed wiring portion 72N with the opposed portions facing each other, it is possible to suppress heat reception of the capacitor element 20N due to heat generated in the power supply wiring 60N, reduce parasitic inductance in the negative electrode-side first capacitor connection wiring 70N. In addition, since the opposed portion of the first opposed wiring portion 71P and the opposed portion of the first opposed wiring portion 71N are opposed, and the opposed portion of the second opposed wiring portion 72P and the opposed portion of the second opposed wiring portion 72N are arranged facing each other, the parasitic inductance in the positive electrode-side first capacitor connection wiring 70P can be further reduced, a noise absorption effect by the capacitor element 20P can be enhanced, the parasitic inductance in the negative electrode-side first capacitor connection wiring 70N can be further reduced, and a noise absorption effect by the capacitor element 20N can be enhanced.

Note that, in the power conversion device according to the eleventh embodiment, the first capacitor connection wiring 70P may be arranged to face the capacitor element 20N or the second capacitor connection wiring 80N so that the common mode noise current CIP flowing through the positive electrode-side first capacitor connection wiring 70P flows in a direction opposite to the common mode noise current CIN flowing through the negative electrode-side capacitor element 20N or the negative electrode-side second capacitor connection wiring 80N.

In addition, in the power conversion device according to the eleventh embodiment, the capacitor element 20P may be disposed to face the first capacitor connection wiring 70N, the capacitor element 20N, or the second capacitor connection wiring 80N so that the common mode noise current CIP flowing through the positive electrode-side capacitor element 20P flows in the opposite direction to the common mode noise current CIN flowing through the negative electrode-side first capacitor connection wiring 70N, the negative electrode-side capacitor element 20N, or the negative electrode-side second capacitor connection wiring 80N.

Furthermore, in the power conversion device according to the eleventh embodiment, the second capacitor connection wiring 80P may be disposed to face the first capacitor connection wiring 70N, the capacitor element 20N, or the second capacitor connection wiring 80N so that the common mode noise current CIP flowing through the positive electrode-side second capacitor connection wiring 80P flows in the opposite direction to the common mode noise current CIN flowing through the negative electrode-side first capacitor connection wiring 70N, the negative electrode-side capacitor element 20N, or the negative electrode-side second capacitor connection wiring 80N.

Note that, also in the power conversion device according to the eleventh embodiment, as described in the second embodiment, the positive electrode-side power supply wiring 60P and the first capacitor connection wiring 70P may be integrally formed, and the positive electrode-side power supply wiring 60N and the first capacitor connection wiring 70N may be integrally formed.

In addition, also in the power conversion device according to the eleventh embodiment, as described in the third embodiment, the first opposed wiring portion 71P and the second opposed wiring portion 72P in the first capacitor connection wiring 70P may be configured as separate components and connected to each other, or the first opposed wiring portion 71N and the second opposed wiring portion 72N in the first capacitor connection wiring 70N may be configured as separate components and connected to each other.

Furthermore, also in the power conversion device according to the eleventh embodiment, as described in the fourth embodiment, the length of the second capacitor connection wiring 80P may be made shorter than the length of the first capacitor connection wiring 70P, and the length of the second capacitor connection wiring 80N may be made shorter than the length of the first capacitor connection wiring 70N.

Furthermore, also in the power conversion device according to the eleventh embodiment, as described in the fifth embodiment, the first capacitor connection wiring 70P and the capacitor element 20P may be integrally formed, and the first capacitor connection wiring 70N and the capacitor element 20N may be integrally formed.

Also in the power conversion device according to the eleventh embodiment, as described in the sixth embodiment, the capacitor element 20P may be disposed facing the opposed portion of the second opposed wiring portion 72P so that the current direction of the common mode noise current CIP flowing through the capacitor element 20P faces the opposed portion of the second opposed wiring portion 72P in the first capacitor connection wiring 70P, and the capacitor element 20N may be disposed facing the opposed portion of the second opposed wiring portion 72N in the first capacitor connection wiring 70N so that the current direction of the common mode noise current CIN flowing through the capacitor element 20N faces the opposed portion of the second opposed wiring portion 72N.

Also in the power conversion device according to the eleventh embodiment, as described in the seventh embodiment, the opposed portion facing the current direction of the common mode noise current CIP flowing through the capacitor element 20P may be provided in the second capacitor connection wiring 80P, and the opposed portion facing the current direction of the common mode noise current CIN flowing through the capacitor element 20N may be provided in the second capacitor connection wiring 80N.

Also in the power conversion device according to the eleventh embodiment, as described in the eighth embodiment, a capacitor element which is a flat plate-like conductor and includes one electrode terminal 21P and the other electrode terminal 22P may be used as the capacitor element 20P, a surface of one electrode terminal 21P of the capacitor element 20P may be disposed facing a surface of an opposed portion of the first opposed wiring portion 71P of the first capacitor connection wiring 70P, a distal end surface of one electrode terminal 21P of the capacitor element 20P may be electrically and mechanically connected to the other end surface of the opposed portion of the second opposed wiring portion 72P of the first capacitor connection wiring 70P, and a capacitor element which is a flat plate-like conductor and includes one electrode terminal 21N and the other electrode terminal 22N may be used as the capacitor element 20N, a surface of one electrode terminal 21N of the capacitor element 20N may be disposed facing the surface of the opposed portion of the first opposed wiring portion 71N of the first capacitor connection wiring 70N, and a distal end surface of one electrode terminal 21N of the capacitor element 20N may be electrically and mechanically connected to the other end surface of the opposed portion of the second opposed wiring portion 72N of the first capacitor connection wiring 70N.

Also in the power conversion device according to the eleventh embodiment, as described in the ninth embodiment, the resistance element 85P connected in series with the capacitor element 20P may be provided, or the resistance element connected in series with the capacitor element 20N may be provided.

Also in the power conversion device according to the eleventh embodiment, as described in the tenth embodiment, at least a part of the resistance element 85P connected in series with the capacitor element 20P may be disposed to face at least one component of the first opposed wiring portion 71P and the second opposed wiring portion 72P of the first capacitor connection wiring 70P, the capacitor element 20P, and the second capacitor connection wiring 80P in which the common mode noise current CIP has a relationship in mutually opposite directions, and at least a part of the resistance element 85P connected in series with the capacitor element 20P may be disposed to face at least one component of the first opposed wiring portion 71N and the second opposed wiring portion 72N of the first capacitor connection wiring 70N, the capacitor element 20N, and the second capacitor connection wiring 80N in which the common mode noise current CIN has a relationship in mutually opposite directions.

### Twelfth Embodiment

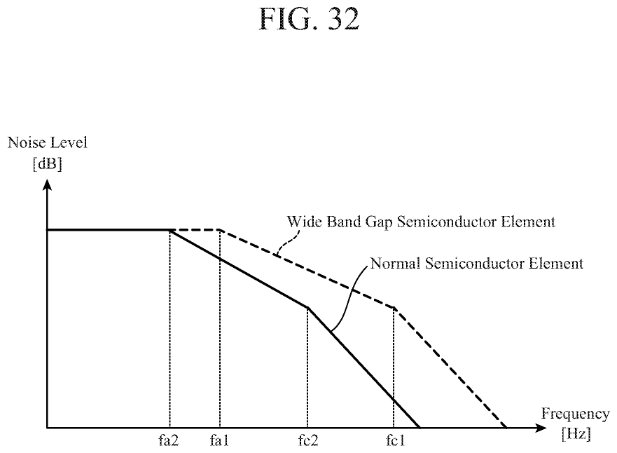

A power conversion device according to a twelfth embodiment will be described with reference to FIGS. 31 and 32.

The power conversion device according to the twelfth embodiment is characterized in that, in the power conversion device according to the first embodiment, wide band gap semiconductor elements are used as the semiconductor switching elements of the semiconductor switching element groups 13u, 14u, 13v, 14v, 13w, and 14w constituting the power conversion circuit 10.

Since the other configurations of the power conversion device according to the twelfth embodiment are the same as those of the power conversion device according to the first embodiment, a wide band gap semiconductor element (Hereinafter, it is abbreviated as a wide-gap semiconductor element.) will be mainly described.

The wide-gap semiconductor element is a semiconductor element having a wider band gap than a semiconductor element using a semiconductor material of silicon (Si) or gallium arsenide (GaAs) which is generally used, and is a semiconductor element using a semiconductor material of silicon carbide (SiC) or gallium nitride (GaN).

The semiconductor material of the wide-gap semiconductor element has physical properties such as high values of thermal conductivity, electron speed, and dielectric breakdown electric field strength, and when the wide-gap semiconductor element is used as the semiconductor switching elements of the semiconductor switching element groups 13u, 14u, 13v, 14v, 13w, and 14w constituting the power conversion circuit 10, the power conversion circuit 10 can be significantly downsized and highly efficient.

That is, the power conversion device according to the twelfth embodiment can suppress heat reception of the capacitor element 20P due to heat generated in the power supply wiring 60P in the electric path from the power supply wiring 60P to the ground node via the capacitor element 20P, reduce the parasitic inductance of the first capacitor connection wiring 70P in the electric path from the power supply wiring 60P to the ground node via the capacitor element 20P, and enhance the noise absorption effect by the capacitor element 20P without impairing the function as a filter for the common mode noise current CI, which is a high frequency in the capacitor element 20P, in the power conversion device that is downsized and improved in efficiency by using the wide-gap semiconductor elements as the semiconductor switching elements of the semiconductor switching element groups 13u, 14u, 13 v, 14v, 13w, and 14w constituting the power conversion circuit 10.

FIG. 31 illustrates on-off drive characteristics in a case where a wide-gap semiconductor element is used as a switching element. For comparison, FIG. 31 also illustrates on-off drive characteristics in a case where a normal semiconductor element using silicon is used as a switching element.

In FIG. 31, a horizontal axis represents time, a vertical axis represents a signal level, a broken line represents an on-off drive characteristic of a wide-gap semiconductor element, and a solid line represents an on-off drive characteristic of a normal semiconductor element.

As is clear from FIG. 31, the rise time tr11 from off to on and the fall time tr12 from on to off in the wide-gap semiconductor element are shorter than the rise time tr21 and the fall time tr22 of the normal semiconductor element, and the pulse application time Ton1 in the wide-gap semiconductor element can also be made shorter than the pulse application time Ton2 in the normal semiconductor element.

As a result, when the wide-gap semiconductor element is used as the switching element, it is possible to achieve high-speed and high-frequency switching operation.

That is, by using a wide-gap semiconductor element as a semiconductor switching element constituting the power conversion circuit 10, a power conversion device that achieves high-speed and high-frequency operation can be obtained.

On the other hand, FIG. 32 illustrates frequency characteristics with respect to noise in a case where a wide-gap semiconductor element is used as a switching element. For comparison, FIG. 32 also illustrates frequency characteristics with respect to noise in a case where a normal semiconductor element using silicon is used as a switching element.

In FIG. 32, a horizontal axis represents a frequency, a vertical axis represents a noise level, a broken line represents a frequency characteristic of a wide-gap semiconductor element, and a solid line represents a frequency characteristic of a normal semiconductor element.

In FIG. 32, fa1 represents a frequency at which the noise level in the wide-gap semiconductor element starts to attenuate at 20 dB/decade, fa2 represents a frequency at which the noise level in the normal semiconductor element starts to attenuate at 20 dB/decade, fc1 represents a frequency at which the noise level in the wide-gap semiconductor element starts to attenuate at 40 dB/decade, and fc2 represents a frequency at which the noise level in the normal semiconductor element starts to attenuate at 40 dB/decade.

As is clear from FIG. 32, the frequency fa1 at which the noise level starts to attenuate at 20 dB/decade in the wide-gap semiconductor element is shifted to the high frequency side more than the frequency fa2 at which the noise level starts to attenuate at 20 dB/decade in the normal semiconductor element, and the frequency fc1 at which the noise level starts to attenuate at 40 dB/decade in the wide-gap semiconductor element is shifted to the high frequency side more than the frequency fc2 at which the noise level starts to attenuate at 40 dB/decade in the normal semiconductor element.

This can also be understood from the following.

That is, the frequency fa at which the noise level starts to attenuate at 20 dB/decade is expressed by the following Formula (10), and the frequency fc at which the noise level starts to attenuate at 40 dB/decade is expressed by the following Formula (11).

fa=1/(π×Ton) (10)

fc=1/(π×tr) (11)

In Formula (10), Ton represents a pulse application time, and tr represents a rise time and a fall time.

Therefore, as is clear from the above Formula (10), when the pulse application time Ton is shortened, the frequency fa increases, and as is clear from the above Formula (11), when the rise time and the fall time tr are shortened, the frequency fc increases.

When a wide-gap semiconductor element is used as a semiconductor switching element constituting the power conversion circuit 10 to achieve high-speed and high-frequency operation, the frequency fa and the frequency fc are increased. However, as described in the first embodiment, since the first capacitor connection wiring 70P has the first opposed wiring portion 71P and the second opposed wiring portion 72P, and at least a part of each of the first opposed wiring portion 71P and the second opposed wiring portion 72P are arranged to face each other, the parasitic inductance of the first capacitor connection wiring 70P can be reduced, and the noise absorption effect by the capacitor element 20P can be enhanced without impairing the function as a filter for the common mode noise current CI that is a high frequency in the capacitor element 20P.

As described above, the power conversion device according to the twelfth embodiment can achieve downsizing and high efficiency by using the wide-gap semiconductor element as the semiconductor switching element constituting the power conversion circuit 10, and as described in the first embodiment, it is possible to suppress heat reception of the capacitor element 20P due to heat generated in the positive electrode-side power supply wiring 60P by the first capacitor connection wiring 70P, and it is possible to reduce parasitic inductance in the first capacitor connection wiring 70P to enhance a noise absorption effect by the capacitor element 20P.

Note that, in the power conversion device according to the twelfth embodiment, in the structure of the electric path from the negative electrode-side power supply wiring 60N to the ground node via the negative electrode-side noise-removing capacitor element 20N shown in the first embodiment, by adopting a structure in which the negative electrode-side first capacitor connection wiring 70N includes the first opposed wiring portion and the second opposed wiring portion, and at least a part of each of the first opposed wiring portion and the second opposed wiring portion P is arranged to face each other, it is possible to suppress heat reception of the capacitor element 20N due to heat generated in the negative electrode-side power supply wiring 60N by the first capacitor connection wiring 70N, and it is possible to reduce parasitic inductance in the first capacitor connection wiring 70N to enhance the noise absorption effect by the capacitor element 20P.

Further, in the power conversion device according to the twelfth embodiment, in the structure of the electric path from the positive electrode-side power supply wiring 60P to the negative electrode-side power supply wiring 60N via the smoothing capacitor element 20S shown in the first embodiment, by adopting a structure in which the positive electrode-side first capacitor connection wiring 70S has the first opposed wiring portion and the second opposed wiring portion, and at least a part of each of the first opposed wiring portion and the second opposed wiring portion P are arranged to face each other, it is possible to suppress the heat reception of the capacitor element 20S due to the heat generated in the positive electrode-side power supply wiring 60P by the first capacitor connection wiring 70S, and it is possible to reduce the parasitic inductance in the first capacitor connection wiring 70S to enhance the noise absorption effect by the capacitor element 20P.

Also in the first to eleventh embodiments, wide band gap semiconductor elements may be used as the semiconductor switching elements of the semiconductor switching element groups 13u, 14u, 13v, 14v, 13w, and 14w constituting the power conversion circuit 10.

Note that it is possible to freely combine the embodiments, to modify any components of the embodiments, or to omit any components of the embodiments.

In addition, various features, aspects, and functions described in one or more embodiments are not limited to the application of the described embodiments, and can be applied to other embodiments alone or in combination.

### INDUSTRIAL APPLICABILITY

The power conversion device according to the present disclosure is used in a power conversion device such as an inverter and a converter in the power electronics field, and is particularly suitable for a power conversion device for an electric power train such as a hybrid vehicle and an electric vehicle.

### REFERENCE SIGNS LIST

100: power supply, 200: load, 300: power conversion device, 10: power conversion circuit, 13u, 14u, 13v, 14v, 13w, 14w: semiconductor switching element group, 20P: capacitor element, 20N: capacitor element, 20S: smoothing capacitor, 30: voltage sensor circuit, 40u: current sensor circuit, 40v: current sensor circuit, 40w: current sensor circuit, 50: control unit, 60P: positive electrode-side power supply wiring, 60N: negative electrode-side power supply wiring, 70P: first capacitor connection wiring, 71P: first opposed wiring portion, 72P: second opposed wiring portion, 73P: bent wiring portion, 80P: second capacitor connection wiring, 85P: snubber resistance, 70N: first capacitor connection wiring, 71N: first opposed wiring portion, 72N: second opposed wiring portion, 73N: bent wiring portion, 80N: second capacitor connection wiring, 70S: first capacitor connection wiring, 80S: second capacitor connection wiring, 91uU, 91uD, 91vU, 91vD, 91wU, 91wD: control line, 92V, 92uI, 92vI, 92wI: signal line

What is claimed is:

1. A power conversion device comprising:
a power conversion circuit including semiconductor switching elements;
a power supply wiring electrically connected to the power conversion circuit;
a capacitor element; and
a first capacitor connection wiring electrically connected between the power supply wiring and one electrode of the capacitor element and including a first opposed wiring portion having a first end electrically connected to the power supply wiring and a second opposed wiring portion having a second end electrically connected to the one electrode of the capacitor element and disposed facing the first opposed wiring portion.

2. The power conversion device according to claim 1, wherein
the power conversion circuit is an inverter circuit that converts a direct current into an alternating current,
the power supply wiring is a positive electrode-side power supply wiring, a first end of the positive electrode-side power supply wiring is connected to a positive electrode-side input terminal to which a positive electrode of a DC power supply is connected, and a second end of the positive electrode-side power supply wiring is connected to a positive electrode-side input terminal of the inverter circuit,
the capacitor element is a positive electrode-side capacitor element for noise removal, and
a second capacitor connection wiring electrically connected between the other electrode of the positive electrode-side capacitor element and a ground node is provided.

3. The power conversion device according to claim 1, wherein
the power conversion circuit is an inverter circuit that converts a direct current into an alternating current,
the power supply wiring is a negative electrode-side power supply wiring, a first end of the negative electrode-side power supply wiring is connected to a negative electrode-side input terminal to which a negative electrode of a DC power supply is connected, and a second end of the negative electrode-side power supply wiring is connected to a negative electrode-side input terminal of the inverter circuit,
the capacitor element is a negative electrode-side capacitor element for noise removal, and
a second capacitor connection wiring electrically connected between the other electrode of the negative electrode-side capacitor element and a ground node is provided.

4. The power conversion device according to claim 1, wherein
the power conversion circuit is an inverter circuit that converts a direct current into an alternating current,
the power supply wiring is a positive electrode-side power supply wiring, a first end of the positive electrode-side power supply wiring is connected to a positive electrode-side input terminal to which a positive electrode of a DC power supply is connected, and a second end of the positive electrode-side power supply wiring is connected to a positive electrode-side input terminal of the inverter circuit,
the capacitor element is a smoothing capacitor element, and
a second capacitor connection wiring electrically connected between a negative electrode-side power supply wiring having a first end connected to a negative electrode-side input terminal to which a negative electrode of the DC power supply is connected and a second end connected to a negative electrode-side input terminal of the inverter circuit and the other electrode of the smoothing capacitor element is provided.

5. The power conversion device according to claim 1, wherein
the first capacitor connection wiring includes a bent wiring portion that electrically connects a second end of the first opposed wiring portion and a first end of the second opposed wiring portion, and
the first capacitor connection wiring is a flat plate-like conductor in which the first opposed wiring portion, the second opposed wiring portion, and the bent wiring portion are integrally formed.

6. The power conversion device according to claim 1, wherein the power supply wiring and the first capacitor connection wiring are integrally formed of the same material.

7. The power conversion device according to claim 1, wherein the first opposed wiring portion and the second opposed wiring portion in the first capacitor connection wiring are separate components.

8. The power conversion device according to claim 2, wherein a length of the second capacitor connection wiring is shorter than a length of the first capacitor connection wiring.

9. The power conversion device according to claim 1, wherein the first capacitor connection wiring and one electrode of the capacitor element are integrally formed.

10. The power conversion device according to claim 1, wherein the capacitor element is disposed such that at least a part of a current direction between one electrode and the other electrode faces at least a part of an opposed wiring portion of at least one of the first opposed wiring portion and the second opposed wiring portion of the first capacitor connection wiring.

11. The power conversion device according to claim 2, wherein the capacitor element is disposed such that at least a part of a current direction between one electrode and the other electrode faces at least a part of the second capacitor connection wiring.

12. The power conversion device according to claim 1, wherein
the capacitor element includes: a main body having the one electrode and the other electrode inside the main body and having a pair of side surfaces each of which is parallel to corresponding one of the one electrode and the other electrode; one electrode terminal electrically connected to the one electrode, positioned on one side surface side of the pair of side surfaces of the main body, and protruding from the main body in one direction of the main body; and the other electrode terminal positioned on the other side surface side of the pair of side surfaces of the main body, and protruding from the main body in one direction of the main body, and
a surface of one electrode terminal of the capacitor element is disposed facing a surface of the first opposed wiring portion, and a distal end of the one electrode terminal of the capacitor element is electrically and mechanically connected to a second end of the second opposed wiring portion.

13. The power conversion device according to claim 1, further comprising a resistance element electrically connected in series to the capacitor element.

14. The power conversion device according to claim 2, further comprising
a resistance element electrically connected in series to the capacitor element, wherein
the resistance element is disposed to face at least one component of a first opposed wiring portion and a second opposed wiring portion of the first capacitor connection wiring, the capacitor element, and the second capacitor connection wiring in which flowing noise currents are in opposite directions to each other.

15. A power conversion device comprising:
a power conversion circuit including semiconductor switching elements;
a positive electrode-side power supply wiring having a first end connected to a positive electrode-side input terminal to which a positive electrode of a DC power supply is connected and a second end connected to a positive electrode-side input terminal of the power conversion circuit;
a negative electrode-side power supply wiring having a first end connected to a negative electrode-side input terminal to which a negative electrode of the DC power supply is connected and a second end connected to a negative electrode-side input terminal of the power conversion circuit;
a positive electrode-side capacitor element for noise removal;
a negative electrode-side capacitor element for noise removal;
a positive electrode-side first capacitor connection wiring electrically connected between the positive electrode-side power supply wiring and one electrode of the positive electrode-side capacitor element;
a negative electrode-side first capacitor connection wiring electrically connected between the negative electrode-side power supply wiring and one electrode of the negative electrode-side capacitor element;
a positive electrode-side second capacitor connection wiring electrically connected between the other electrode of the positive electrode-side capacitor element and a ground node; and
a negative electrode-side second capacitor connection wiring electrically connected between the other electrode of the negative electrode-side capacitor element and the ground node, wherein
in at least one positive electrode-side component of the positive electrode-side first capacitor connection wiring, the positive electrode-side capacitor element, and the positive electrode-side second capacitor connection wiring, and at least one negative electrode-side component of the negative electrode-side first capacitor connection wiring, the negative electrode-side capacitor element, and the negative electrode-side second capacitor connection wiring, the positive electrode-side component and the negative electrode-side component in which flowing noise currents are in opposite directions to each other are arranged to face each other.

16. The power conversion device according to claim 15, wherein
the positive electrode-side first capacitor connection wiring includes a positive electrode-side first opposed wiring portion having a first end electrically connected to the positive electrode-side power supply wiring, and a positive electrode-side second opposed wiring portion having a second end electrically connected to one electrode of the positive electrode-side capacitor element and disposed facing the positive electrode-side first opposed wiring portion, and
the negative electrode-side first capacitor connection wiring includes a negative electrode-side first opposed wiring portion having a first end electrically connected to the negative electrode-side power supply wiring, and a negative electrode-side second opposed wiring portion having a second end electrically connected to one electrode of the positive electrode-side capacitor element and disposed facing the negative electrode-side first opposed wiring portion.

17. The power conversion device according to claim 1, wherein the semiconductor switching element is a wide band gap semiconductor element.

18. The power conversion device according to claim 15, wherein the semiconductor switching element is a wide band gap semiconductor element.
